(19) United States
(12) Patent Application Publication
(10) Pub. No.: US 2026/0090254 A1
(43) Pub. Date: Mar. 26, 2026

(54) DISPLAY APPARATUS

(71) Applicant: LG Display Co., Ltd., Seoul (KR)

(72) Inventors: Junehwan KIM, Paju-si (KR); Seongil KIM, Paju-si (KR); Youngmin OH, Paju-si (KR)

(73) Assignee: LG Display Co., Ltd., Seoul (KR)

(21) Appl. No.: 19/315,131

(22) Filed: Aug. 29, 2025

(30) Foreign Application Priority Data
Sep. 23, 2024 (KR) 10-2024-0127949

(51) Int. Cl. H10K 59/80; H10K 59/35; H10K 59/38

(52) U.S. Cl. CPC H10K 59/879; H10K 59/35; H10K 59/38; H10K 59/877; H10K 59/878; H10K 59/8792

(57) ABSTRACT

A display apparatus can include a display panel, a grid layer disposed on the display panel and having a base portion and a protrusion portion protruding from the base portion, and a cover layer disposed on the grid layer. The grid layer includes a plurality of optical interference particles. The plurality of optical interference particles are disposed in the base portion and the protrusion portion.

### CROSS-REFERENCE TO RELATED APPLICATION

The present application claims priority to Korean Patent Application No. 10-2024-0127949, filed in the Republic of Korea on Sep. 23, 2024, the entire contents of which is incorporated by reference into the present application.

### BACKGROUND

### Field of the Invention

The present specification relates to a display apparatus.

### Discussion of the Related Art

As the information society develops, various demands for display apparatuses for displaying images are increasing, and various types of display apparatuses, such as a liquid crystal display (LCD) apparatus and an organic light-emitting diode (OLED) display apparatus, are being utilized.

Among the display apparatuses, there is an advantage in that the OLED display apparatus as the self-luminous type has a wider viewing angle and a high contrast ratio, and is lighter and thinner and has less power consumption than the LCD apparatus because it does not require a separate backlight. In addition, there is an advantage in that the OLED display apparatus can drive at a low voltage, have a fast response time, and especially have the inexpensive manufacturing cost. The OLED display apparatus can also be applied to display apparatuses mounted on vehicles.

With the advancement of the technology of display apparatuses, the display apparatuses are required to not only display images on their screens, but also have interior aesthetics, design simplification, and design integration with surrounding objects.

### SUMMARY OF THE DISCLOSURE

The present disclosure is directed to providing a display apparatus in which it is possible to implement an improved visual sense.

The present disclosure is also directed to providing a display apparatus in which it is possible to implement the same texture as the visual sense.

The present disclosure is also directed to providing a display apparatus in which, even when the visual sense and the same texture as the visual sense are implemented, it is possible to minimize a reduction in luminance.

The present disclosure is also directed to providing a display apparatus that can have improved aesthetics and can be integrated with surroundings.

The present disclosure is also directed to providing an improved display apparatus, which addresses the limitations and disadvantages associated with the related art.

Objects of the present disclosure are not limited to the above-described objects, and other technical objects can be inferred from the following embodiments.

According to one or more embodiments of the present disclosure, there is provided a display apparatus including a display panel, a grid layer disposed on the display panel and including a base portion and a protrusion portion protruding from the base portion, and a cover layer disposed on the grid layer, wherein the grid layer includes a plurality of optical interference particles.

According to another embodiment of the present disclosure, there is provided a display apparatus including a substrate, a thin film transistor disposed on the substrate, a light-emitting part disposed on the thin film transistor and connected to the thin film transistor, an encapsulation part disposed on the light-emitting part, a touch layer disposed on the encapsulation part, a color filter disposed on the touch layer, a deco layer disposed on the color filter, and a cover layer disposed on the deco layer, in which the deco layer is disposed between the color filter and the cover layer and includes a plurality of optical interference particles.

Detailed matters of other embodiments of the present disclosure are included in the detailed description and accompanying drawings.

According to the embodiments of the present disclosure, it is possible to implement the improved visual sense.

According to the embodiments of the present disclosure, it is possible to implement the same texture as the visual sense.

According to the embodiments of the present disclosure, even when the visual sense and the same texture as the visual sense are implemented, it is possible to minimize a reduction in luminance.

According to the embodiments of the present disclosure, it is possible to provide the display apparatus that can have the improved aesthetics and can be integrated with surroundings.

According to the embodiments of the present disclosure, even when the visual sense and the texture are implemented, it is possible to minimize a reduction in luminance and implement low power of the display apparatus, thereby reducing power consumption.

However, effects obtainable from the present disclosure are not limited to the above-described effects, and other effects that are not mentioned will be able to be clearly understood by those skilled in the art to which the present disclosure pertains based on the following description.

### BRIEF DESCRIPTION OF THE DRAWINGS

The present disclosure will become more fully understood from the detailed description given hereinbelow and the accompanying drawings which are given by way of illustration only, and thus are not limitative of the present disclosure.

FIG. 1 is a plan view of a display apparatus according to one or more embodiments of the present disclosure.

FIG. 2 is an enlarged view of area Q1 in FIG. 1.

FIG. 3 is a cross-sectional structure of the display apparatus according to one embodiment of the present disclosure.

FIG. 4 is a specific cross-sectional view of a light-emitting part of FIG. 3.

FIG. 5 is a specific cross-sectional view of a light-emitting part according to a modified example of the present disclosure.

FIG. 6 is a cross-sectional view of a touch part according to FIG. 3.

FIG. 7 is a specific cross-sectional view of a display panel according to the modified example of the present disclosure.

FIG. 8 is an enlarged view of area Q2 in FIG. 3.

FIG. 9 is a cross-sectional view of optical interference particles according to one embodiment of the present disclosure.

FIG. 10 is a cross-sectional view of a display apparatus according to another embodiment of the present disclosure.

FIG. 11 is a cross-sectional view of a display apparatus according to still another embodiment of the present disclosure.

FIG. 12 is a plan view of a display apparatus according to yet another embodiment of the present disclosure.

FIG. 13 is a cross-sectional view along line A-A′ in FIG. 12.

FIG. 14 is a cross-sectional view along line B-B′ in FIG. 12.

FIG. 15 is a cross-sectional view of a display apparatus according to yet another embodiment of the present disclosure.

### DETAILED DESCRIPTION OF THE EMBODIMENTS

Hereinafter, embodiments of the present disclosure will be described with reference to the accompanying drawings. In the specification, when a first component (or an area, a layer, a portion, etc.) is described as “on,” “connected,” or “coupled to” a second component, it means that the first component can be directly connected/coupled to the second component or a third component can be disposed therebetween.

The same reference numerals indicate the same components. In addition, in the drawings, thicknesses, proportions, and dimensions of components are exaggerated for effective description of technical contents. The term “and/or” includes all one or more combinations that can be defined by the associated configurations. Further, the term “can” fully encompasses all the meanings and coverages of the term “may” and vice versa.

Terms such as first and second can be used to describe various components, but the components are not limited by the terms. The terms are used only for the purpose of distinguishing one component from another. For example, a first component can be referred to as a second component, and similarly, the second component can also be referred to as the first component without departing from the scopes of the embodiments. The singular includes the plural unless the context clearly dictates otherwise.

Terms such as “under,” “at a lower side,” “above,” and “at an upper side” are used to describe the relationship between the components illustrated in the drawings. The terms are relative concepts and are described with respect to directions marked in the drawings.

It should be understood that term such as “includes” or “has” is intended to specify the presence of features, numbers, steps, operations, components, parts, or a combination thereof described in the specification and does not preclude the presence or addition possibility of one or more other features, numbers, steps, operations, components, parts, or combinations thereof in advance.

Now, various embodiments of the present disclosure will be discussed referring to the drawings. All the components of each display apparatus/device according to all embodiments of the present disclosure are operatively coupled and configured.

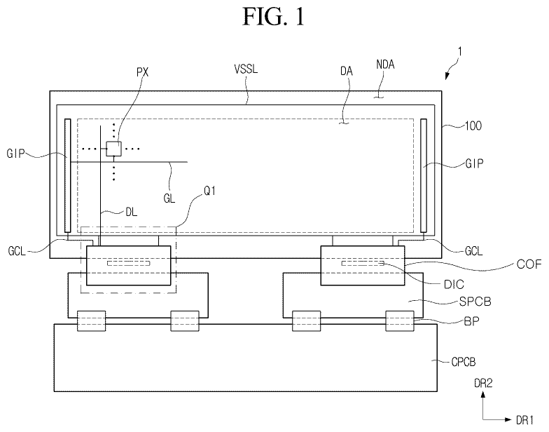

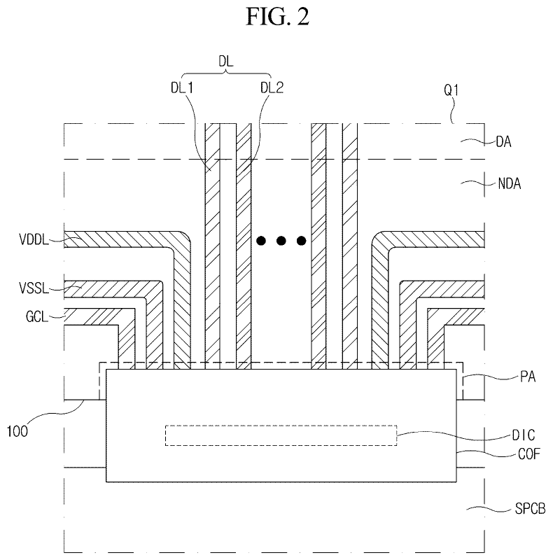

FIG. 1 is a plan view of a display apparatus according to one embodiment of the present disclosure. FIG. 2 is an enlarged view of area Q1 in FIG. 1.

Referring to FIGS. 1 and 2, a display apparatus 1 can be an apparatus including both a display function of displaying an image and a touch sensing function of sensing a user's touch, but is not limited thereto. For example, the display apparatus 1 can include only one of the display function of displaying an image and the touch sensing function of sensing a user's touch.

The display apparatus 1 can be an electroluminescent display apparatus or a micro light-emitting diode display apparatus that includes a touch sensor. The electroluminescent display apparatus including the touch sensor can be an organic light-emitting diode (OLED) display apparatus, a quantum-dot light-emitting diode display apparatus, or an inorganic light-emitting diode display apparatus.

The display apparatus 1 according to the present embodiment can be a vehicle display apparatus, but is not limited thereto. The description of the display apparatus 1 can be applied without limitation to the type of an apparatus as long as the apparatus is an apparatus including a display function. For example, the display apparatus 1 can be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an e-book, a portable multimedia player (PMP), a personal digital assistant (PDA), an MP3 player, a mobile medical device, a desktop PC, a laptop PC, a netbook computer, a workstation, a navigation system, a vehicle display apparatus, a theater display apparatus, a television, a wallpaper device, a signage device, a game device, a laptop computer, a monitor, a camera, a camcorder, a home appliances, etc.

When the display apparatus 1 according to the present embodiment is a vehicle display apparatus, the display apparatus 1 can include a function of manipulating at least some of various functions of a vehicle, a function of displaying various pieces of information about the vehicle, etc.

When the display apparatus 1 according to the present embodiment is a vehicle display apparatus, the display apparatus 1 can be disposed on a dashboard of a vehicle. The display apparatus 1 can be disposed across a driver's seat and a front passenger's seat that are disposed at front seats of a vehicle, but is not limited thereto.

Both a driver DRIVER sitting on the driver's seat and a passenger CO-DRIVER sitting on the front passenger's seat can use the display apparatus 1. The display apparatus 1 can provide different images to each of the driver DRIVER sitting on the driver's seat and the passenger CO-DRIVER sitting on the front passenger's seat. However, the embodiments of the present disclosure are not limited thereto, and the display apparatus 1 can provide the same image to both the driver DRIVER sitting on the driver's seat and the passenger CO-DRIVER sitting on the front passenger's seat.

The display apparatus 1 can include a display panel 100. The display panel 100 can include a display area DA and a non-display area NDA.

The display area DA can be an area in which light is emitted to the outside to display a screen. The display area DA can further include a function of sensing a user's touch. In this case, the display area DA can correspond to a touch sensing area, but is not limited thereto.

The display area DA can correspond to the shape of the display panel 100, but is not limited thereto.

The display panel 100 can include a plurality of pixels PX. The plurality of pixels PX can be disposed in the display area DA. The plurality of pixels PX can be repeatedly disposed in a first direction DR1 and a second direction DR2.

The non-display area NDA can be an area in which light is not emitted to the outside so as not to display a screen. The non-display area NDA can be located around the display area DA. The non-display area NDA can surround the display area DA, but the embodiments of the present disclosure are not limited thereto. A bezel area of the display apparatus 1 can be defined by the non-display area NDA, but the embodiments of the present disclosure are not limited thereto.

The display panel 100 can be a rigid display panel, but is not limited thereto. The display panel 100 can be a flexible display panel of which shape can be deformed, such as a foldable, bendable, rollable, or stretchable display panel.

The display panel 100 can include a long side and a short side that form an edge of the display panel 100. The long side can extend in the first direction DR1, and the short side can extend in the second direction DR2.

The first direction DR1 and the second direction DR2 can be directions intersecting each other. The first direction DR1 and the second direction DR2 can be orthogonal, but are not limited thereto. The first direction DR1 and the second direction DR2 are provided to clarify the description of the invention, the first direction DR1 and the second direction DR2 are relative, and the embodiments of the present disclosure are not limited thereto.

The display apparatus 1 can further include a gate driving unit GIP, a source printed circuit board SPCB, a flexible film COF, a drive integrated circuit (IC) DIC, a control printed circuit board CPCB, a connection member BP, a gate line GL, a gate control line GCL, a data line DL, a low-potential voltage line VSSL, a high-potential voltage line VDDL, and a pad area PA connected to the above components.

The pad area PA can overlap the flexible film COF. The pad area PA can be attached to the flexible film COF. For example, the display panel 100 and the flexible film COF can be attached through the pad area PA.

The pad area PA can be disposed in the non-display area NDA. The pad area PA can include a plurality of pads. The pad area PA can include a plurality of pads connected to the gate line GL, the gate control line GCL, the data line DL, the low-potential voltage line VSSL, and the high-potential voltage line VDDL.

The pad area PA can be provided as a plurality of pad areas. When the pad area PA is provided as a plurality of pad areas, the gate control pad GCP can be omitted from some pad areas PA. For example, the plurality of pad areas PAs can be repeatedly disposed in the first direction DR1, and the gate control pad GCP can be omitted from the remaining pad areas PA excluding the pad areas PA disposed at both ends in the first direction DR1.

The gate driving unit GIP can be disposed in the non-display area NDA. The gate driving unit GIP can be disposed at at least one of one side and the other side of the display area DA in the first direction DR1, but is not limited thereto. In a plan view, the gate driving unit GIP can be disposed at the left side and the other side of the display area DA.

The gate driving unit GIP can include a plurality of transistors. Transistors disposed in the gate driving unit GIP can be connected to the pixels PX through the gate lines GL. The gate driving unit GIP can apply a gate signal to each pixel PX through the gate line GL.

The gate driving unit GIP can receive a gate control signal from the drive IC DIC through the gate control line GCL. The gate driving unit GIP can generate a scan signal and a light-emitting signal (or a light-emitting control signal) based on the gate control signal.

The gate driving unit GIP can include a scan driver and a light-emitting signal driver. The scan driver can generate a scan signal in a row-sequential manner and supply the scan signal to the scan lines in order to drive one or more scan lines connected to each pixel PX row. The light-emitting signal driver can generate a light-emitting signal in a row-sequential manner and supply the light-emitting signal to light-emitting signal lines in order to drive one or more light-emitting signal lines connected to each pixel PX row.

The source printed circuit board SPCB can be connected to the display panel 100 through the flexible film COF. The source printed circuit board SPCB can be electrically connected to the pixel PX of the display area DA through the flexible film COF. The source printed circuit board SPCB can be electrically connected to the flexible film COF. The source printed circuit board SPCB and the flexible film COF can be electrically connected through the plurality of pads VSSP, VDDP, and DP.

The source printed circuit board SPCB can have various types of components disposed to supply various signals, such as a gate control signal, a driving signal, a data signal, and the like, to the driving IC DIC. The source printed circuit board SPCB can be a PCB, but is not limited thereto.

The source printed circuit board SPCB can be connected to the display panel 100 through the flexible film COF in the non-display area NDA. The source printed circuit board SPCB can be provided as a plurality of source printed circuit boards along the non-display area NDA, but is not limited thereto. The number of source printed circuit boards SPCBs can vary according to a design.

The flexible film COF can be connected to the display panel 100 and the source printed circuit board SPCB. The flexible film COF can be attached to each of the display panel 100 and the source printed circuit board SPCB and electrically connected to each of the display panel 100 and the source printed circuit board SPCB. For example, the display panel 100 and the source printed circuit board SPCB can be electrically connected through the flexible film COF. The flexible film COF can be provided as a plurality of flexible films, but is not limited thereto.

The flexible film COF can be attached to the display panel 100 in the non-display area NDA. The flexible film COF can be repeatedly disposed along the non-display area NDA.

A single source printed circuit board SPCB can be electrically connected to the display panel 100 through at least one flexible film COF. A plurality of source printed circuit boards SPCBs disposed along the non-display area NDA can be electrically connected to the display panel 100 through one flexible film COF, but are not limited thereto. For example, the source printed circuit board SPCB can be electrically connected to the display panel 100 through two or more flexible films COFs.

The flexible film COF can be electrically connected to the pad area PA. Accordingly, the flexible film COF can supply gate control signals, driving signals, power voltages, data voltages, etc. to the plurality of pixels PX and the gate driving unit GIP that are disposed in the display area DA.

The flexible film COF can be a flexible insulating film. The flexible film COF can include, for example, polycarbonate, polyethylene terephthalate, polyimide, polyamide, polyester, polyacrylate, polymethyl methacrylate, etc., but is not limited thereto.

The drive IC DIC can be mounted on the flexible film COF. The drive IC DIC can be disposed by a method of a chip on glass, a chip on film, a tape carrier package, etc. according to a mounting method. In the present disclosure, the drive IC DIC is described as being mounted on the flexible film COF by the chip on film method, but is not limited thereto.

The drive IC DIC can drive the display apparatus 1. The drive IC DIC can process data signals for displaying an image, various driving signals for processing the data signals, etc. The drive IC DIC can include a gate driver IC, a data driver IC, etc.

The control printed circuit board CPCB can be connected to the source printed circuit board SPCB through the connection member BP. The control printed circuit board CPCB can be electrically connected to the source printed circuit board SPCB through the connection member BP. The control printed circuit board CPCB can be electrically connected to the connection member BP.

The control printed circuit board CPCB can be provided with a controller for controlling the operation of a data driving circuit, a gate driving circuit, etc., and a power management integrated circuit (PMIC) for supplying various types of voltages or currents to or controlling various types of voltages or currents, which will be supplied to the display panel 100, the data driving circuit, the gate driving circuit, etc.

The control printed circuit board CPCB can be a PCB, but is not limited thereto.

The connection member BP can be connected to the source printed circuit board SPCB and the control printed circuit board CPCB. The connection member BP can be attached to each of the source printed circuit board SPCB and the control printed circuit board CPCB and electrically connected to each of the source printed circuit board SPCB and the control printed circuit board CPCB.

For example, the source printed circuit board SPCB and the control printed circuit board CPCB can be electrically connected through the connection member BP.

One control printed circuit board CPCB can be electrically connected to the source printed circuit board SPCB through at least one connection member BP. A plurality of control printed circuit boards CPCB disposed along the non-display area NDA can be electrically connected to the source printed circuit board SPCB through a single connection member BP, but are not limited thereto. For example, the control printed circuit board CPCB can be electrically connected to the source printed circuit board SPCB through two or more connection members BPs.

The connection member BP can be a flexible insulating film. The connection member BP can be a flexible printed circuit (FPC), a flexible flat cable (FFC), etc., but is not limited thereto.

The source printed circuit board SPCB and the control printed circuit board CPCB are configured separately, but are not limited thereto. For example, at least one source printed circuit board SPCB and the control printed circuit board CPCB can be implemented by being integrated into a single printed circuit board.

The gate line GL can be extended from the gate driving unit GIP and connected to the pixel PX. The gate line GL can electrically connect the gate driving unit GIP and the pixel PX. The gate line GL can apply the gate signal from the gate driving unit GIP to each pixel PX.

The gate control line GCL can be disposed in the non-display area NDA. The gate control line GCL can extend from the pad area PA to the gate driving unit GIP and can be electrically connected to the gate driving unit GIP.

The gate control line GCL can apply the gate control signal to the gate driving unit GIP. The gate control signal can be transmitted from the control printed circuit board CPCB, the source printed circuit board SPCB, or the drive IC DIC. The gate control line GCL can electrically connect the gate driving unit GIP to the control printed circuit board CPCB, the source printed circuit board SPCB, or the drive IC DIC.

The data line DL can extend from the pad area PA and can be connected to the pixel PX of the display area DA. The data line DL can apply the data signal to each pixel PX. The data signal can be applied from the control printed circuit board CPCB, the source printed circuit board SPCB, or the drive IC DIC. The data line DL can electrically connect the pixel PX to the control printed circuit board CPCB, the source printed circuit board SPCB, or the drive IC DIC.

The data line DL can be disposed on a different layer and can include a first data line DL1 and a second data line DL2 that are formed of different conductive layers. However, the embodiments of the present disclosure are not limited thereto.

The low-potential voltage line VSSL can be disposed in the non-display area NDA to surround the display area DA. The low-potential voltage line VSSL can be disposed in the non-display area NDA with the display area DA and the gate driving unit GIP interposed therebetween. For example, the gate driving unit GIP can be disposed between the display area DA and the low-potential voltage line VSSL.

The low-potential voltage line VSSL can apply a low-potential voltage to the pixel PX. The low-potential voltage line VSSL can be electrically connected to the cathode electrode of the pixel PX to apply a low-potential voltage.

The high-potential voltage line VDDL can be disposed between the display area DA and the low-potential voltage line VSSL. The high-potential voltage line VDDL can apply a high-potential voltage to the pixel PX. The high-potential voltage line VDDL can be electrically connected to the anode electrode of the pixel PX to apply the high-potential voltage.

Hereinafter, a cross-sectional structure of the display apparatus 1 according to embodiment of the present disclosure will be described in detail.

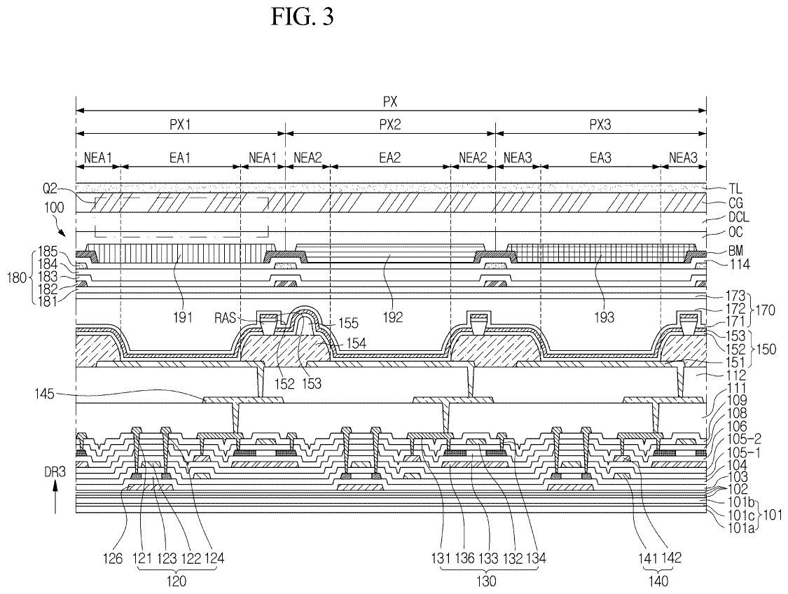

FIG. 3 is a cross-sectional structure of the display apparatus according to one embodiment of the present disclosure. Particularly, FIG. 3 illustrates a cross-sectional structure of the pixel PX of FIG. 1. Each pixel PX of FIG. 1 can have the configuration shown in FIG. 3.

Referring to FIG. 3, the pixel PX (see FIG. 1) of the display panel 100 can include a plurality of sub-pixels PX1, PX2, and PX3. A first sub-pixel PX1 can be a red sub-pixel, a second sub-pixel PX2 can be a green sub-pixel, and a third sub pixel PX3 can be a blue sub-pixel, but the embodiments of the present disclosure are not limited thereto. Each of the sub-pixels PX1, PX2, and PX3 can have substantially the same structure.

In some embodiments, the pixel PX further includes a fourth sub-pixel, and the fourth sub-pixel can be a white sub-pixel, but the embodiments of the present disclosure are not limited thereto. In some embodiments, the pixel can include one red sub-pixel, two green sub-pixels, and one blue sub-pixel, but the embodiments of the present disclosure are not limited thereto. For example, the plurality of sub-pixels PX1, PX2, and PX3 can be arranged in a stripe manner in the first direction DR1, but are not limited thereto, and can be arranged in a pentile manner.

The display panel 100 can include a substrate 101, a first thin film transistor 120, a second thin film transistor 130, a light-emitting part 150, an encapsulation part 170, a touch part 180, a filter insulating layer 114, a black matrix BM, color filters 191, 192, and 193, and a planarization layer OC. The display panel 100 can include at least one panel insulating layer and at least one touch insulating layer between the substrate 101 and the light-emitting part 150. The at least one panel insulating layer can include at least one of a buffer layer 102, a first insulating layer 103, a second insulating layer 104, a 3-1 insulating layer 105-1, a 3-2 insulating layer 105-2, a fourth insulating layer 106, a fifth insulating layer 108, a sixth insulating layer 109, a first protective layer 111, and a second protective layer 112, and the at least one touch insulating layer can include at least one of a touch buffer layer 181, a first touch insulating layer 183, and a second touch insulating layer 184.

The substrate 101 can provide a space in which various components can be disposed thereon. The substrate 101 can correspond to the flat surface shape of the display panel 100 of FIG. 1.

The substrate 101 can include one or more plastic materials. For example, the substrate 101 can be a multi-substrate including a plurality of plastic materials, such as polyimide, etc. For example, the substrate 101 can include a first substrate portion 101a and a second substrate portion 101b each including a plastic material, and a third substrate portion 101c including an inorganic insulation material between the first substrate portion 101a and the second substrate portion 101b, but the embodiments of the present disclosure are not limited thereto.

The substrate 101 can include a rigid substrate. However, the embodiments of the present disclosure are not limited thereto, and the substrate 101 can include a flexible substrate.

The buffer layer 102 can be disposed on the substrate 101. The buffer layer 102 can minimize or delay the diffusion of moisture or oxygen penetrating the substrate 101. The buffer layer 102 can be formed by alternately stacking silicon nitride (SiNₓ) and silicon oxide (SiOₓ) at least once, but the embodiments of the present disclosure are not limited thereto.

A first light-blocking layer 126 can be disposed on the buffer layer 102. The first light-blocking layer 126 can prevent light from transmitting a first semiconductor layer 123 of the first thin film transistor 120. For example, the first semiconductor layer 123 can be disposed to overlap the first light-blocking layer 126. The first light-blocking layer 126 can be formed of a single layer or multiple layers formed of one of molybdenum (Mo), aluminum (Al), chromium (Cr), nickel (Ni), neodymium (Nd), and copper (Cu) or an alloy thereof, but the embodiments of the present disclosure are not limited thereto.

The first insulating layer 103 can be disposed on the buffer layer 102 and the first light-blocking layer 126. The first insulating layer 103 can prevent a short circuit between a component of the first thin film transistor 120 and the first light-blocking layer 126. The first insulating layer 103 can be formed of the same material as the buffer layer 102, but the embodiments of the present disclosure are not limited thereto. For example, the first insulating layer 103 can be formed of an inorganic insulation material, such as silicon nitride (SiNₓ) or silicon oxide (SiOₓ), but the embodiments of the present disclosure are not limited thereto.

The first thin film transistor 120 can be disposed on the first insulating layer 103. The first thin film transistor 120 can include a first source electrode 121, a first gate electrode 122, the first semiconductor layer 123, and a first drain electrode 124.

The first semiconductor layer 123 can be disposed on the first insulating layer 103. The first semiconductor layer 123 can include a metal oxide semiconductor, such as indium-gallium-zinc oxide (IGZO), and a silicon-based semiconductor material, such as amorphous silicon, polycrystalline silicon, etc., but the embodiments of the present disclosure are not limited thereto. The first semiconductor layer 123 can include a channel area, a source area, and a drain area.

Since the polycrystalline semiconductor layer has higher mobility than the amorphous semiconductor layer and the oxide semiconductor layer, power consumption can be less, and reliability can be excellent. Accordingly, a driving transistor can be formed of the polycrystalline semiconductor layer.

The second insulating layer 104 can be disposed on the first semiconductor layer 123. The second insulating layer 104 can be formed of the same material as the first insulating layer 103 and can prevent a short circuit between the first semiconductor layer 123 and another component of the first thin film transistor 120.

The first gate electrode 122 can be disposed on the second insulating layer 104. The first gate electrode 122 can be disposed on the second insulating layer 104 to overlap the channel area of the first semiconductor layer 123. The first gate electrode 122 can be formed of a single layer or multiple layers formed of molybdenum (Mo), copper (Cu), titanium (Ti), aluminum (Al), chromium (Cr), gold (Au), nickel (Ni), neodymium (Nd), or a compound thereof, but the embodiments of the present disclosure are not limited thereto. The first gate electrode 122 can be disposed along with a gate line.

The third insulating layers 105-1 and 105-2 can be disposed on the first gate electrode 122. The third insulating layers 105-1 and 105-2 can be formed by alternately stacking silicon nitride (SiNₓ) and silicon oxide (SiOₓ) at least once, but the embodiments of the present disclosure are not limited thereto. For example, the 3-1 insulating layer 105-1 can include silicon oxide (SiOₓ), and the 3-2 insulating layer 105-2 can include silicon nitride (SiNₓ), but the embodiments of the present disclosure are not limited thereto.

The first source electrode 121 and the first drain electrode 124 can be disposed on the third insulating layers 105-1 and 105-2.

The first source electrode 121 and the first drain electrode 124 can be electrically connected to the first semiconductor layer 123 through contact holes. The first source electrode 121 and the first drain electrode 124 can be formed of a metallic material. For example, the first source electrode 121 and the first drain electrode 124 can be formed of a single layer or multiple layers formed of one of molybdenum (Mo), aluminum (Al), chromium (Cr), gold (Au), titanium (Ti), nickel (Ni), neodymium (Nd), and copper (Cu) or an alloy thereof, but the embodiments of the present disclosure are not limited thereto.

The first source electrode 121 and the first drain electrode 124 can be disposed along with a data line. For example, the data line can be formed of the same material as the first source electrode 121 and the first drain electrode 124 and formed on the same layer as the first source electrode 121 and the first drain electrode 124, but the embodiments of the present disclosure are not limited thereto.

A storage electrode 140 can be disposed to be spaced apart from the first thin film transistor 120. The storage electrode 140 can include a first storage electrode 141 and a second storage electrode 142.

The first storage electrode 141 can be formed of the same material as the first gate electrode 122 and disposed on the same layer as the first gate electrode 122, but the embodiments of the present disclosure are not limited thereto.

The second storage electrode 142 can be disposed on the first storage electrode 141. The second storage electrode 142 can be disposed on the third insulating layers 105-1 and 105-2, and the third insulating layers 105-1 and 105-2 between the first storage electrode 141 and the second storage electrode 142 can be used as a dielectric to generate a capacitance. The second storage electrode 142 can be formed of the same material as the first storage electrode 141, but the embodiments of the present disclosure are not limited thereto.

The second thin film transistor 130 can be disposed to be spaced apart from the first thin film transistor 120 and the storage electrode 140. The second thin film transistor 130 can include a second source electrode 131, a second gate electrode 132, a second semiconductor layer 133, and a second drain electrode 134.

A second light-blocking layer 136 can be disposed on the same layer as the second storage electrode 142.

The second light-blocking layer 136 can prevent light from traveling to the second semiconductor layer 133 similar to the first light-blocking layer 126, thereby extending the life of the second thin film transistor 130. For example, the second semiconductor layer 133 can be disposed to overlap the second light-blocking layer 136.

The fourth insulating layer 106 can be disposed on the second light-blocking layer 136. The fourth insulating layer 106 can be formed of the same material as the first insulating layer 103, the second insulating layer 104, or the third insulating layers 105-1 and 105-2, but the embodiments of the present disclosure are not limited thereto.

The second semiconductor layer 133 can be disposed on the fourth insulating layer 106. The second semiconductor layer 133 can include a source area, a drain area, and a channel area between the source area and the drain area.

The second semiconductor layer 133 can include a metal oxide semiconductor, such as indium-gallium-zinc oxide (IGZO), and a silicon-based semiconductor material, such as amorphous silicon, polycrystalline silicon, etc., but the embodiments of the present disclosure are not limited thereto.

The fifth insulating layer 108 can be disposed on the second semiconductor layer 133. The fifth insulating layer 108 can be formed of the same material as the first insulating layer 103, the second insulating layer 104, the third insulating layers 105-1 and 105-2, or the fourth insulating layer 106, but the embodiments of the present disclosure are not limited thereto.

The second gate electrode 132 can be disposed on the fifth insulating layer 108.

The second gate electrode 132 can be formed of the same material as the first gate electrode 122. For example, the second gate electrode 132 can be formed of a single layer or multiple layers formed of molybdenum (Mo), copper (Cu), titanium (Ti), aluminum (Al), chromium (Cr), gold (Au), nickel (Ni), neodymium (Nd), or a compound thereof, but the embodiments of the present disclosure are not limited thereto.

The sixth insulating layer 109 can be disposed on the second gate electrode 132. The sixth insulating layer 109 can be formed of the same material as the first insulating layer 103, the second insulating layer 104, the third insulating layers 105-1 and 105-2, the fourth insulating layer 106, or the fifth insulating layer 108, but the embodiments of the present disclosure are not limited thereto.

The first source electrode 121, the first drain electrode 124, the second source electrode 131, and the second drain electrode 134 can be disposed on the sixth insulating layer 109.

The second source electrode 131 and the second drain electrode 134 can be formed of the same material as the first source electrode 121 and the first drain electrode 124 and disposed on the same layer as the first source electrode 121 and the first drain electrode 124, but the embodiments of the present disclosure are not limited thereto. For example, the second source electrode 131 and the second drain electrode 134 can be formed of a single layer or multiple layers formed of any one of molybdenum (Mo), aluminum (Al), chromium (Cr), gold (Au), titanium (Ti), nickel (Ni), neodymium (Nd), and copper (Cu) or an alloy thereof, but the embodiments of the present disclosure are not limited thereto. For example, the second source electrode 131 can be electrically connected to the second storage electrode 142. The second source electrode 131 can pass through the sixth insulating layer 109, the fifth insulating layer 108, and the fourth insulating layer 106 and can be electrically connected to the second storage electrode 142.

The first thin film transistor 120 can be a driving transistor, and the second thin film transistor 130 can be a switching transistor, but the embodiments of the present disclosure are not limited thereto.

A first protective layer 111 can be disposed on the first source electrode 121 and the first drain electrode 124.

The first protective layer 111 can planarize upper portions of the first thin film transistor 120 and the second thin film transistor 130 and protect the first thin film transistor 120 and the second thin film transistor 130. The first protective layer 111 can be formed of an organic material. For example, the first protective layer 111 can be formed of an organic material including an acrylic resin, an epoxy resin, a phenolic resin, a polyamide resin, or a polyimide resin, but the embodiments of the present disclosure are not limited thereto.

A second protective layer 112 can be disposed on the first protective layer 111. The second protective layer 112 can be formed of the same material as the first protective layer 111, but the embodiments of the present disclosure are not limited thereto.

In some embodiments, a third protective layer can be further disposed on an upper surface of the second protective layer 113, but the embodiments of the present disclosure are not limited thereto.

A connection electrode 145 can be disposed between the first protective layer 111 and the second protective layer 112.

The connection electrode 145 can electrically connect the first thin film transistor 120 to the light-emitting part 150. The connection electrode 145 can be formed of the same material as the first source electrode 121 and the first drain electrode 124, but the embodiments of the present disclosure are not limited thereto.

The connection electrode 145 can be formed of a single layer or multiple layers formed of one of molybdenum (Mo), aluminum (Al), chromium (Cr), gold (Au), titanium (Ti), nickel (Ni), neodymium (Nd), and copper (Cu) or an alloy thereof, but the embodiments of the present disclosure are not limited thereto.

The light-emitting part 150 can be disposed on the second protective layer 112. The light-emitting part 150 can include an anode electrode 151, an organic layer 152, and a cathode electrode 153. The anode electrode 151 can serve as an anode, and the cathode electrode 153 can serve as a cathode.

The anode electrode 151 can be disposed on the second protective layer 112. The anode electrode 151 can be electrically connected to the first thin film transistor 120 through a contact hole formed in the second protective layer 112. The anode electrode 151 can be a reflective electrode that reflects light, but the embodiments of the present disclosure are not limited thereto. The anode electrode 151 can include a metallic material with high reflectivity, such as a stacking structure (Ti/Al/Ti) of aluminum (Al) and titanium (Ti), a stacking structure (ITO/Al/ITO) of aluminum (Al) and indium tin oxide (ITO), or an APC alloy and can be formed of a single layer or multiple layers, but the embodiments of the present disclosure are not limited thereto.

The organic layer 152 can be disposed on the anode electrode 151. The organic layer 152 can include one or more light-emitting structures (or light-emitting elements or elements) stacked on the anode electrode 151 in the order or reverse order of a hole transfer layer and an electron transfer layer. For example, the hole transfer layer can include a hole transporting layer, a hole injecting layer, an electron blocking layer, a p-type charge generation layer, etc., but the embodiments of the present disclosure are not limited thereto. For example, the electron transfer layer can include an electron transporting layer, an electron injecting layer, a hole blocking layer, an n-type charge generation layer, etc., but the embodiments of the present disclosure are not limited thereto. The organic layer 152 can be an organic light-emitting layer, an inorganic light-emitting layer, a quantum dot light-emitting layer, a micro light-emitting diode, a micro mini light-emitting diode, etc., but the embodiments of the present disclosure area not limited thereto. For example, the organic layer 152 of the display panel 100 according to one embodiment of the present disclosure can include an organic light-emitting layer. The organic layer 152 can include a red light-emitting layer, a green light-emitting layer, and a blue light-emitting layer. The organic layer 152 can be a white light-emitting layer, but the embodiments of the present disclosure are not limited thereto.

Hereinafter, a specific structure of the organic layer 152 according to one embodiment of the present disclosure will be described.

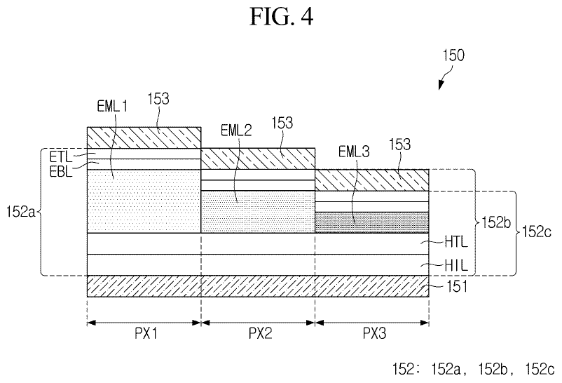

FIG. 4 is a specific cross-sectional view of a light-emitting part of FIG. 3.

Referring to FIG. 4, the light-emitting part 150 can include the first sub-pixel PX1, the second sub-pixel PX2, and the third sub-pixel PX3.

A thickness of the light-emitting part 150 in each sub-pixel PX1, PX2, or PX3 can be different, but the embodiments of the present disclosure are not limited thereto, and the thickness of the light-emitting part 150 in each sub-pixel PX1, PX2, or PX3 can be the same.

The organic layer 152 can include a first organic layer 152a disposed in the first sub-pixel PX1, a second organic layer 152b disposed in the second sub-pixel PX2, and a third organic layer 152c disposed in the third sub-pixel PX3. The light-emitting layers EML1, EML2, and EML3 of the organic layers 152a, 152b, and 152c can be physically separated, but lower layers and upper layers of the light-emitting layers EML1, EML2, and EML3 can be formed integrally across the sub-pixels PX1, PX2, and PX3. A thicknesses of each light-emitting layer EML1, EML2, or EML3 can be different. For example, a thickness of a first light-emitting layer EML1 can be the greatest, a thickness of a second light-emitting layer EML2 can be the second greatest, and a thickness of the third light-emitting layer EML3 can be the smallest, but the embodiments of the present disclosure are not limited thereto.

The hole injecting layer HIL can be disposed on the anode electrode 151. The hole injecting layer HIL can be located between the anode electrode 151 and the light-emitting layers EML1, EML2, and EML3. The hole injecting layer HIL can be formed integrally across the sub-pixels PX1, PX2, and PX3. For example, the hole injecting layer HIL can be formed of a hole injecting material that is one selected from MTDATA, CuPc, TCTA, NPB (NPD), HATCN, TDAPB, PEDOT/PSS, F4TCNQ, N-(biphenyl-4-yl)-9,9-dimethyl-N-(4-(9-phenyl-9H-carbazol-3-yl)phenyl)-9H-fluoren-2-amine, etc., but the embodiments of the present disclosure are not limited thereto.

A hole transporting layer HTL can be disposed on the hole injecting layer HIL. The hole transporting layer HTL can be located between the hole injecting layer HIL and the light-emitting layers EML1, EML2, and EML3. The hole transporting layer HTL can be formed integrally across the sub-pixels PX1, PX2, and PX3. The hole transporting layer HTL can be formed of one or more selected from the group consisting of arylamine-based materials, such as NPB (N,N-naphthyl-N,N′-phenyl benzidine), TPD (N,N′-bis-(3-methylphenyl)-N,N′-bis-(phenyl)-benzidine), PPD, TTBND, FFD, p-dmDPS, and TAPC, starbust aromatic amine-based materials, such as TCTA, PTDATA, TDAPB, TDBA, 4-a, and TCTA, and spiro and ladder type materials, such as Spiro-TPD, Spiro-mTTB, and Spiro-2, NPD (N,N-dinaphthylN,N′-diphenyl benzidine), s-TAD, and MTDATA(4,4′,4″-Tris(N-3-methylphenyl-N-phenyl-amino)-triphenylamine), but the embodiments of the present disclosure are not limited thereto.

The light-emitting layers EML1, EML2, and EML3 can be disposed on the hole transporting layer HTL. The first light-emitting layer EML1 can be disposed in the first sub-pixel PX1, the second light-emitting layer EML2 can be disposed in the second sub-pixel PX2, and the third light-emitting layer EML3 can be disposed in the third sub-pixel PX3.

A thicknesses of each light-emitting layer EML1, EML2, or EML3 can be different. For example, the first light-emitting layer EML1 can be formed in a thickness of 600 to 800 angstroms (10⁻¹⁰ meters), the second light-emitting layer EML2 can be formed in a thickness of 300 to 500 angstroms (10⁻¹⁰ meters), and the third light-emitting layer EML3 can be formed in a thickness of 100 to 300 angstroms (10⁻¹⁰ meters), but the embodiments of the present disclosure are not limited thereto.

Each of the first light-emitting layer EML1, the second light-emitting layer EML2, and the third light-emitting layer EML3 can include a material that can emit light in the visible light range by receiving and combining holes and electrons.

An electron blocking layer EBL can be disposed on each light-emitting layer EML1, EML2, or EML3. The electron blocking layer EBL can be disposed integrally across the sub-pixels PX1, PX2, and PX3.

An electron transporting layer ETL can be disposed on the electron blocking layer EBL. The electron transporting layer ETL can be disposed integrally across the sub-pixels PX1, PX2, and PX3. The electron transporting layer ETL can be formed of an anthracene derivative and lithium quinolate (Liq) or formed of one or more selected from oxadiazole, triazole, phenanthroline, benzoxazole, benzthiazole, or benzimidazole (e.g., 2-[4-(9,10-Di-2-naphthalenyl-2-anthracenyl)phenyl]-1-phenyl-1H-benzimidazole), but the embodiments of the present disclosure are not limited thereto.

The cathode electrode 153 can be disposed on the electron transporting layer ETL.

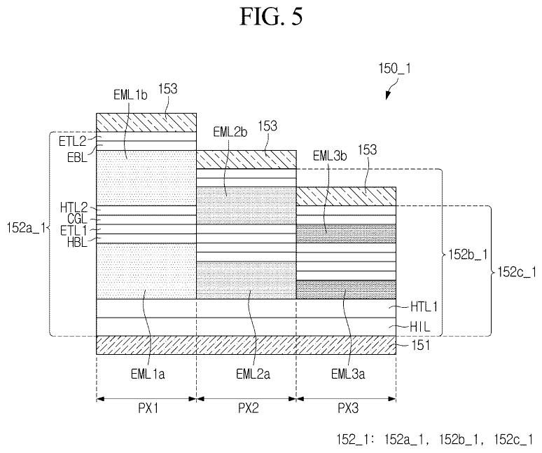

FIG. 5 is a specific cross-sectional view of a light-emitting part according to a modified example of the present disclosure.

Referring to FIGS. 4 and 5, an organic layer 152_1 can include a first organic layer 152a_1 disposed in the first sub-pixel PX1, a second organic layer 152b_1 disposed in the second sub-pixel PX2, and a third organic layer 152c_1 disposed in the third sub-pixel PX3.

The light-emitting layers of each organic layer 152a_1, 152b_1, or 152c_1 can be physically separated, but the lower layers and upper layers of the light-emitting layers can be formed integrally across the sub-pixels PX1, PX2, and PX3. The thickness of each light-emitting layer can be different. For example, the thickness of the first light-emitting layer of the first sub-pixel can be the greatest, the thickness of the second light-emitting layer of the second sub-pixel can be the second greatest, and the thickness of the third light-emitting layer of the third sub-pixel can be the smallest, but the embodiments of the present disclosure are not limited thereto. In addition, the light-emitting layers of each organic layer 152a_1, 152b_1, or 152c_1 can be provided as two or more light-emitting layers.

The hole injecting layer HIL can be disposed on the anode electrode 151. The hole injecting layer HIL can be located between the anode electrode 151 and the light-emitting layers EML1a, EML2a, and EML3a. The hole injecting layer HIL can be formed integrally across the sub-pixels PX1, PX2, and PX3. For example, the hole injecting layer HIL can be formed of a hole injecting material that is one selected from MTDATA, CuPc, TCTA, NPB (NPD), HATCN, TDAPB, PEDOT/PSS, F4TCNQ, N-(biphenyl-4-yl)-9,9-dimethyl-N-(4-(9-phenyl-9H-carbazol-3-yl)phenyl)-9H-fluoren-2-amine, etc., but the embodiments of the present disclosure are not limited thereto.

A first hole transporting layer HTL1 can be disposed on the hole injecting layer HIL. The first hole transporting layer HTL1 can be located between the hole injecting layer HIL and light-emitting layers EML1a, EML2a, and EML3a. The first hole transporting layer HTL1 can be formed integrally across the sub-pixels PX1, PX2, and PX3. The first hole transporting layer HTL1 can be formed of one or more selected from the group consisting of arylamine-based materials, such as NPB (N,N-naphthyl-N,N′-phenyl benzidine), TPD (N,N′-bis-(3-methylphenyl)-N,N′-bis-(phenyl)-benzidine), PPD, TTBND, FFD, p-dmDPS, and TAPC, starbust aromatic amine-based materials, such as TCTA, PTDATA, TDAPB, TDBA, 4-a, and TCTA, and spiro and ladder type materials, such as Spiro-TPD, Spiro-mTTB, and Spiro-2, NPD (N,N-dinaphthylN,N′-diphenyl benzidine), s-TAD, and MTDATA(4,4′,4″-Tris(N-3-methylphenyl-N-phenyl-amino)-triphenylamine), but the embodiments of the present disclosure are not limited thereto.

The light-emitting layers EML1a, EML2a, and EML3a can be disposed on the first hole transporting layer HTL1. A 1-1 light-emitting layer EML1a can be disposed in the first sub-pixel PX1, a 2-1 light-emitting layer EML2a can be disposed in the second sub-pixel PX2, and a 3-1 light-emitting layer EML3a can be disposed in the third sub-pixel PX3. Each of the light-emitting layers EML1a, EML2a, and EML3a can be the same as each of the light-emitting layers EML1, EML2, and EML3 of FIG. 4.

A thicknesses of each light-emitting layer EML1a, EML2a, or EML3a can be different. For example, the 1-1 light-emitting layer EML1a can be formed in a thickness of 600 to 800 angstroms (10⁻¹⁰ meters), the 2-1 light-emitting layer EML2a can be formed in a thickness of 300 to 500 angstroms (10⁻¹⁰ meters), and the 3-1 light-emitting layer EML3a can be formed in a thickness of 100 to 300 angstroms (10⁻¹⁰ meters), but the embodiments of the present disclosure are not limited thereto.

A hole blocking layer HBL can be disposed on each light-emitting layer EML1a, EML2a, or EML3a. The hole blocking layer HBL can be disposed integrally across the sub-pixels PX1, PX2, and PX3.

A first hole transporting layer ETL1 can be disposed on the hole blocking layer HBL. The first electron transporting layer ETL1 can be formed integrally across the sub-pixels PX1, PX2, and PX3. The first electron transporting layer ETL1 can be formed of an anthracene derivative and lithium quinolate (Liq) or formed of one or more selected from oxadiazole, triazole, phenanthroline, benzoxazole, benzthiazole, or benzimidazole (e.g., 2-[4-(9,10-Di-2-naphthalenyl-2-anthracenyl)phenyl]-1-phenyl-1H-benzimidazole), but the embodiments of the present disclosure are not limited thereto.

A common charge layer CGL can be disposed on the first electron transporting layer ETL1. The common charge layer CGL can be disposed between the first electron transporting layer ETL1 and the second hole transporting layer HTL2. The common charge layer CGL can include a conductive material, but the embodiments of the present disclosure are not limited thereto.

The second hole transporting layer HTL2 can be disposed on the common charge layer CGL. The second hole transporting layer HTL2 can be disposed between the hole blocking layer HBL and the light-emitting layers EML1b, EML2b, and EBL3b. The second hole transporting layer HTL2 can be formed integrally across the sub-pixels PX1, PX2, and PX3. A material of the second hole transporting layer HTL2 can be the same as a material of the first hole transporting layer HTL1, but the embodiments of the present disclosure are not limited thereto.

The light-emitting layers EML1b, EML2b, and EML3b can be disposed on the second hole transporting layer HTL2. A 1-2 light-emitting layer EML1b can be disposed in the first sub-pixel PX1, a 2-2 light-emitting layer EML2b can be disposed in the second sub-pixel PX2, and a 3-2 light-emitting layer EML3b can be disposed in the third sub-pixel PX3. Each of the light-emitting layers EML1b, EML2b, and EML3b can be the same as each of the light-emitting layers EML1a, EML2a, and EML3a.

A thicknesses of each light-emitting layer EML1b, EML2b, or EML3b can be different. For example, the 1-2 light-emitting layer EML1b can be formed in a thickness of 600 to 800 angstroms (10⁻¹⁰ meters), the 2-2 light-emitting layer EML2b can be formed in a thickness of 300 to 500 angstroms (10⁻¹⁰ meters), and the 3-2 light-emitting layer EML3b can be formed in a thickness of 100 to 300 angstroms (10⁻¹⁰ meters), but the embodiments of the present disclosure are not limited thereto.

An electron blocking layer EBL can be disposed on each light-emitting layer EML1b, EML2b, or EML3b. The electron blocking layer EBL can be disposed integrally across the sub-pixels PX1, PX2, and PX3.

A second hole transporting layer ETL2 can be disposed on the electron blocking layer EBL. The second electron transporting layer ETL2 can be formed integrally across the sub-pixels PX1, PX2, and PX3. The second electron transporting layer ETL2 can be formed of an anthracene derivative and lithium quinolate (Liq) or formed of one or more selected from oxadiazole, triazole, phenanthroline, benzoxazole, benzthiazole, or benzimidazole (e.g., 2-[4-(9,10-Di-2-naphthalenyl-2-anthracenyl)phenyl]-1-phenyl-1H-benzimidazole), but the embodiments of the present disclosure are not limited thereto.

The cathode electrode 153 can be disposed on the second electron transporting layer ETL2.

Referring back to FIG. 3, the cathode electrode 153 can be disposed on the organic layer 152. The cathode electrode 153 can be a transparent electrode that transmits light, but the embodiments of the present disclosure are not limited thereto. For example, the cathode electrode 153 can include a transparent conductive material, such as indium tin oxide (ITO) or indium zinc oxide (IZO), or a metal that transmits visible light, but the embodiments of the present disclosure are not limited thereto.

A bank 154 can be disposed to expose the anode electrode 151. The bank 154 can define openings (or light-emitting areas EA1, EA2, and EA3) of the sub-pixels PX1, PX2, and PX3 and can be disposed to cover an edge portion (or a periphery) of the anode electrode 151. For example, the first sub-pixel PX1 can include a first light-emitting area EA1 and a first non-light-emitting area NEA1 around the first light-emitting area EA1, the second sub-pixel PX2 can include a second light-emitting area EA2 and a second non-light-emitting area NEA2 around the second light-emitting area EA2, and the third sub-pixel PX3 can include a third light-emitting area EA3 and a third non-light-emitting area NEA3 around the third light-emitting area EA3. For example, each non-light-emitting area NEA1, NEA2, or NEA3 can correspond to a boundary between adjacent sub-pixels PX1, PX2, and PX3.

The bank 154 can include a black-based material. For example, the bank 154 can be formed of a material containing black pigment, or an organic material, such as a benzocyclobutene resin, a polyimide resin, an acrylic resin, a photosensitive polymer, etc., but the embodiments of the present disclosure are not limited thereto. When the bank 154 is formed of a material containing black pigment or black dye, the bank 154 can be an opaque bank. When the bank 154 is formed of a material containing black pigment or black dye, it is possible to block external light or light reflected from the outside, thereby further increasing the luminance of the display apparatus.

A barrier RAS can be further disposed on the bank 154. As illustrated in FIG. 3, the barrier RAS can be disposed in all the non-display areas NEA1, NEA2, and NEA3 that are boundaries between the sub-pixels PX1, PX2, and PX3, but the embodiments of the present disclosure are not limited thereto. The barrier RAS can be disposed directly on an upper surface of the bank 154, but the embodiments of the present disclosure are not limited thereto. The barrier RAS can serve to separate the organic layer 152 from the boundaries of adjacent sub-pixels PX1, PX2, and PX3.

A spacer 155 can be further disposed on the bank 154. The spacer 155 can be formed of the same material as the bank 154, but the embodiments of the present disclosure are not limited thereto. For example, the spacer 155 can be a transparent bank, but is not limited thereto, and the spacer 155 can be formed of the same material as the bank 154. For example, the spacer 155 can be disposed on at least one of the boundaries of the first to third sub-pixels PX1, PX2, and PX3, but the embodiments of the present disclosure are not limited thereto. The bank 154 and the spacer 155 can be formed of the same material and formed simultaneously through a halftone mask, but the embodiments of the present disclosure are not limited thereto.

The organic layer 152 can be disposed on the anode electrode 151, the bank 154, and the spacer 155. The cathode electrode 153 can be disposed on the organic layer 152.

The encapsulation part 170 can be disposed on the cathode electrode 153. The encapsulation part 170 can include one or more insulating layers. For example, the encapsulation part 170 can include a first encapsulation layer 171, a second encapsulation layer 172 disposed on the first encapsulation layer 171, and a third encapsulation layer 173 disposed on the second encapsulation layer 172. The encapsulation part 170 can include one or more inorganic insulation material layers and one or more organic material layers. For example, the first encapsulation layer 171 and the third encapsulation layer 173 can include an inorganic insulation material, and the second encapsulation layer 172 can include an organic material, but the embodiments of the present disclosure are not limited thereto.

The touch part 180 can be disposed on the encapsulation part 170. The touch part 180 can include the touch buffer layer 181, a first touch conductive layer, the first touch insulating layer 183, the second touch insulating layer 184, and a second touch conductive layer. In some embodiments, one or more touch organic layers can be further disposed on the second touch conductive layer, but the embodiments of the present disclosure are not limited thereto.

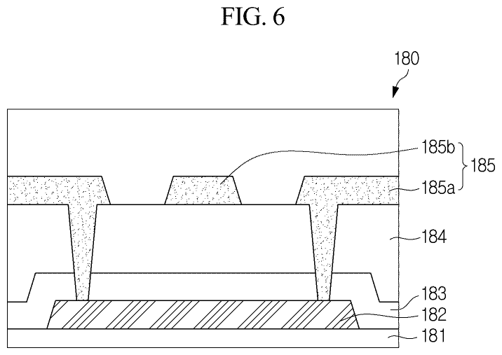

FIG. 6 is a cross-sectional view of a touch part according to FIG. 3 according to an example of the present disclosure.

Referring to FIGS. 3 and 6, the touch buffer layer 181 can be disposed on the encapsulation part 170. For example, a touch buffer layer 181 can be disposed on the third encapsulation layer 173. The touch buffer layer 181 can be formed of the same material as the buffer layer 102, but the embodiments of the present disclosure are not limited thereto.

The first touch conductive layer can be disposed on the touch buffer layer 181. The first touch conductive layer can include a bridge electrode 182. The bridge electrode 182 and a sensor electrode 185 to be described below can be disposed at each of the boundaries between adjacent sub-pixels PX1, PX2, and PX3. For example, the bridge electrode 182 and the sensor electrode 185 can be disposed in the non-light-emitting areas NEA1, NEA2, and NEA3. The bridge electrode 182 and the sensor electrode 185 can overlap the black matrix BM to be described below in the thickness direction. The black matrix BM can cover the bridge electrode 182 and the sensor electrode 185. Accordingly, the bridge electrode 182 and the sensor electrode 185 can be prevented from being visible from the outside.

The first touch insulating layer 183 and the second touch insulating layer 184 disposed on the first touch insulating layer 183 can be disposed on the first touch conductive layer. The first touch insulating layer 183 and the second touch insulating layer 184 disposed on the first touch insulating layer 183 can prevent a short circuit between the first touch conductive layer and the second touch conductive layer. The first touch insulating layer 183 can be formed of silicon oxide (SiOₓ), silicon nitride (SiNₓ), or multiple layers thereof, but the embodiments of the present disclosure are not limited thereto. The second touch insulating layer 184 can include an organic insulation material, but the embodiments of the present disclosure are not limited thereto, and the second touch insulating layer 184 can include the same material as the first touch insulating layer 183.

The second touch conductive layer can be disposed on the second touch insulating layer 184. The second touch conductive layer can include a first sensor electrode 185a and a second sensor electrode 185b. The sensor electrode 185 can include the first sensor electrode 185a extending in the first direction DR1 (see FIG. 1) and the second sensor electrode 185b extending in the second direction DR2 (see FIG. 1) different from the first direction DR1.

The bridge electrode 182 can be electrically connected to the first sensor electrode 185a through a contact hole formed in the first touch insulating layer 183 and the second touch insulating layer 184. For example, the first sensor electrode 185a and the bridge electrode 182 can extend in the first direction DR1 (see FIG. 1).

The sensor electrode 185 and the bridge electrode 182 can include a metallic material. For example, the first touch conductive layer 182 can be formed of titanium (Ti), nickel (Ni), aluminum (Al), or an alloy thereof and formed of a triple layer, such as titanium (Ti)/aluminum (Al)/titanium (Ti), but the embodiments of the present disclosure are not limited thereto.

Referring back to FIG. 3, the filter insulating layer 114 can be disposed on the second touch conductive layer. The filter insulating layer 114 can be formed of an inorganic insulation material, such as silicon nitride (SiNₓ) or silicon oxide (SiOₓ), but the embodiments of the present disclosure are not limited thereto.

The black matrix BM can be disposed on the filter insulating layer 114. The black matrix BM can include a black-based material. For example, the black matrix BM can include a light-blocking material or a light-absorbing material. For example, the black matrix BM can be formed of a material including a black pigment, a black dye, etc. The black matrix BM can cover the bridge electrode 182 and the sensor electrode 185. Accordingly, the bridge electrode 182 and the sensor electrode 185 can be prevented from being visible from the outside. For example, a width of the black matrix BM can be smaller than a width of the bank 154.

For example, spacing distances between an end of the black matrix BM and boundaries between the light-emitting areas EA1, EA2, and EA3 and the non-light-emitting areas NEA1, NEA2, and NEA3 can be longer than spacing distances between an end of the bank 154 and the boundaries between the light-emitting areas EA1, EA2, and EA3 and the non-light-emitting areas NEA1, NEA2, and NEA3. The end of the bank 154 can be aligned with the boundaries between the light-emitting areas EA1, EA2, and EA3 and the non-light-emitting areas NEA1, NEA2, and NEA3, but the embodiments of the present disclosure are not limited thereto. In the case of the display panel 100 according to one embodiment, since the bank 154 can include a black-based material and the spacing distances between an end of the black matrix BM and boundaries between the light-emitting areas EA1, EA2, and EA3 and the non-light-emitting areas NEA1, NEA2, and NEA3 can be longer than spacing distances between an end of the bank 154 and the boundaries between the light-emitting areas EA1, EA2, and EA3 and the non-light-emitting areas NEA1, NEA2, and NEA3, light emitted from the light-emitting areas EA1, EA2, and EA3 can be emitted upward with a greater viewing angle as much as a spacing space between the end of the black matrix BM and the boundaries between the light-emitting areas EA1, EA2, and EA3 and the non-light-emitting areas NEA1, NEA2, and NEA3. Accordingly, it is possible to minimize a reduction in luminance according to a viewing angle. However, when the spacing distances between the end of the black matrix BM and the boundaries between the light-emitting areas EA1, EA2, and EA3 and the non-light-emitting areas NEA1, NEA2, and NEA3 can be longer than the spacing distances between the end of the bank 154 and the boundaries between the light-emitting areas EA1, EA2, and EA3 and the non-light-emitting areas NEA1, NEA2, and NEA3 and the bank 154 is formed of only a transparent material, externally incident light can be reflected by the bank 154, resulting in visible ring-shaped spots. However, in the case of the display panel 100 according to one embodiment, the light incident from the outside can be absorbed or blocked by the bank 154 including a black-based material, thereby preventing the occurrence of the ring-shaped spots.

The color filters 191, 192, and 193 can be disposed on the black matrix BM. The color filters 191, 192, and 193 can be disposed on the first to third sub-pixels PX1, PX2, and PX3, respectively, and can block specific colors from light emitted from the light-emitting area EA1, EA2, and EA3 of the sub-pixels PX1, PX2, and PX3. A first color filter 191 can be provided to block light of other colors not including red (R) light. In this case, the first color filter 191 can be provided as a red color filter. The second color filter 192 can be provided to block light of other colors not including green (G) light. In this case, a second color filter 192 can be provided as a green color filter. A third color filter 193 provided in the third sub-pixel PX3 can be provided to block light of other colors not including blue (B) light. In this case, the third color filter 193 can be provided as a blue color filter. However, the embodiments of the present disclosure are not limited thereto.

For example, each color filter 191, 192, or 193 can come into direct contact with side and upper surfaces of the black matrix BM. For example, each color filter 191, 192, or 193 can be spaced apart from the boundaries of adjacent sub-pixels PX1, PX2, and PX3, but the embodiments of the present disclosure are not limited thereto, and the color filters 191, 192, and 193 can overlap each other in the thickness direction.

The planarization layer OC can be disposed on the color filters 191, 192, and 193. The planarization layer OC can serve to planarize a step formed by the color filters 191, 192, and 193. For example, the planarization layer OC can include an organic insulation material.

The display apparatus 1 can further include a deco layer DCL disposed on the display panel 100, a cover layer CG disposed on the deco layer DCL, and a texture layer TL disposed on the cover layer CG.

The deco layer DCL can be disposed on the planarization layer OC. The deco layer DCL can be disposed in the display area DA. The deco layer DCL can be disposed across the entire area of the display area DA, but is not limited thereto. The deco layer DCL can also be disposed in the non-display area NDA.

The deco layer DCL can implement a visual sense that can provide an aesthetic sense even when the display apparatus 1 is turned off and minimize a deviation according to a viewing angle of the reflected visual sense.

Since the deco layer DCL is disposed between the planarization layer OC and the cover layer CG, it is possible to minimize the configuration that can interference with external light due to the path of the external light incident on the deco layer DCL. Accordingly, the deco layer DCL can more smoothly implement the visual sense, colors, etc.

The deco layer DCL will be described in detail below.

The cover layer CG can be disposed on the deco layer DCL. The cover layer CG can be formed of a glass material including glass, quartz, etc., but the embodiments of the present disclosure are not limited thereto, and the cover layer CG can be formed of a plastic material. The cover layer CG can be disposed above the display panel 100 to protect members disposed under the cover layer CG from the outside. The cover layer CG can be a cover layer formed by chemical reinforcement, but the embodiments of the present disclosure are not limited thereto. The cover layer CG can be a cover window, a window cover, or a cover member, but the embodiments of the present disclosure are not limited thereto.

However, the embodiments of the present disclosure are not limited thereto, and a transparent adhesive member can be further disposed between the deco layer DCL and the cover layer CG. For example, the transparent adhesive member can include at least one of a transparent pressure sensitive adhesive (PSA), an optical clear adhesive (OCA), or an optical clear resin (OCR).

The texture layer TL capable of representing a texture can be disposed on the cover layer CG. The texture layer TL can provide a texture to a user touching the screen of the display apparatus 1. The texture layer TL can include a material capable of representing roughness on a surface or can be manufactured by a manufacturing method capable of representing roughness on the surface. For example, the texture layer TL can implement surface roughness by including at least one of nano-rods and nano-wires. Alternatively, the texture layer TL can include an organic polymer and implement roughness through surface treatment.

Through the texture layer TL, it is possible to provide various textures according to an OFF state visual sense represented on the deco layer DCL so that the user can receive further improved aesthetics and integration with surroundings.

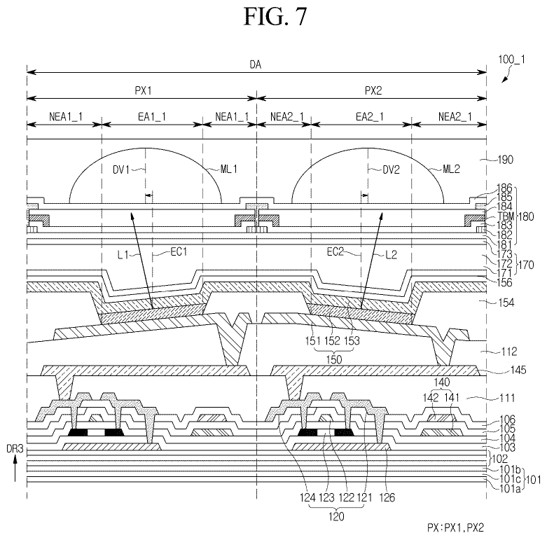

FIG. 7 is a specific cross-sectional view of a display panel according to the modified example.

In FIG. 7, the contents that are substantially the same as those described in FIGS. 3 to 6 will be omitted or briefly described.

Referring to FIG. 7, the display panel 100 can include a plurality of sub-pixels PX1 and PX2. The pixel PX can include a plurality of first sub-pixels PX1 and a plurality of second sub-pixels PX2. The first sub-pixel PX1 and the second sub-pixel PX2 can be disposed in the display area DA.

For example, each of the first sub-pixel PX1 and the second sub-pixel PX2 can be disposed repeatedly in the first direction DR1. The first sub-pixel PX1 and the second sub-pixel PX2 can be alternately disposed repeatedly in the second direction DR2. However, the embodiments of the present disclosure are not limited thereto.

The first sub-pixel PX1 and the second sub-pixel PX2 can include light-emitting areas EA1 and EA2 and non-light-emitting areas NEA1 and NEA2, respectively.

The first sub-pixel PX1 can include the first light-emitting area EA1 and the first non-light-emitting area NEA1 disposed around the first light-emitting area EA1. The second sub-pixel PX2 can include the second light-emitting area EA2 and the second non-light-emitting area NEA2 disposed around the second light-emitting area EA2.

The display panel 100 can include the substrate 101, the thin film transistor 120, the storage electrode 140, the light-emitting part 150, the encapsulation part 170, and the touch part 180 in the display area DA. However, the embodiments of the present disclosure are not limited thereto.

Each pixel PX can include the thin film transistor 120, the storage electrode 140, and the light-emitting part 150.

The substrate 101 can provide a space in which various components can be disposed thereon. The buffer layer 102, the light-blocking layer 126, and the first insulating layer 103 can be disposed sequentially on the substrate 101.

The thin film transistor 120 can be disposed on the first insulating layer 103. The second insulating layer 104 can be disposed on the semiconductor layer 123. The gate electrode 122 and the storage electrode 140 can be disposed on the second insulating layer 104.

The third insulating layer 105 can be disposed on the gate electrode 122.

The storage electrode 140 can be disposed to be spaced apart from the thin film transistor 120. The storage electrode 140 can include the first storage electrode 141 and the second storage electrode 142.

The second storage electrode 142 can be disposed on the first storage electrode 141. Capacitance can be generated using the third insulating layer 105 between the first storage electrode 141 and the second storage electrode 142 as a dielectric.

The fourth insulating layer 106 can be disposed on the second storage electrode 142. The source electrode 121 and the drain electrode 124 can be disposed on the fourth insulating layer 106. The source electrode 121 and the drain electrode 124 can be electrically connected to the semiconductor layer 123 through contact holes.

The thin film transistor 120 can be a driving transistor and the display panel 100 can further include a switching transistor, but the embodiments of the present disclosure are not limited thereto.

The first protective layer 111 can be disposed on the source electrode 121 and the drain electrode 124. The second protective layer 112 can be disposed on the first protective layer 111.

The connection electrode 145 can be disposed between the first protective layer 111 and the second protective layer 112. The light-emitting part 150 can be disposed on the second protective layer 112. The light-emitting part 150 can include the anode electrode 151, the organic layer 152, and the cathode electrode 153.

The anode electrode 151 can be disposed on the second protective layer 112. The organic layer 152 can be disposed on the anode electrode 151. The cathode electrode 153 can be disposed on the organic layer 152.

A capping layer 156 can be further disposed on the cathode electrode 153. The capping layer 156 can minimize damage to the cathode electrode 153 of the light-emitting element 150 and the organic layers 152 located below the cathode electrode 153 from an external light source. The capping layer 156 can be formed of an organic or inorganic film.

The capping layer 156 can be disposed using a material, such as LiF or the like, as an inorganic film and can further include an organic film, but the embodiments of the present disclosure are not limited thereto. For example, the capping layer 156 can be formed of the stacking structure of an organic film and an inorganic film, and a thickness of the organic film can differ from a thickness of the inorganic film. In this case, the thickness of the organic film can be greater than the thickness of the inorganic film. As another example, the capping layer 156 can be formed of two or more layers by stacking materials having different refractive indexes. Accordingly, it is possible to increase the light efficiency of the display panel 100.

The bank 154 can be disposed to expose the anode electrode 151. The bank 154 can define the opening (or the light-emitting area EA of the pixel PX and can be disposed to cover the edge of the anode electrode 151.

The encapsulation part 170 can be disposed on the bank 154 or the light-emitting part 150. The encapsulation part 170 can include one or more insulating layers.

The touch part 180 can be disposed on the encapsulation part 170. The touch part 180 can include the touch buffer layer 181, the first touch electrode 182, the first touch insulating layer 183, a touch black matrix TBM, the second touch insulating layer 184, a second touch electrode 185, and a third touch insulating layer 186.

The touch buffer layer 181 can be disposed on the encapsulation part 170. For example, a touch buffer layer 181 can be disposed on the third encapsulation layer 173. The touch buffer layer 181 can be formed of the same material as the buffer layer 102, but the embodiments of the present disclosure are not limited thereto.

The first touch electrode 182 can be disposed on the touch buffer layer 181. The first touch insulating layer 183 can be disposed on the first touch electrode 182.

The touch black matrix TBM can be disposed on the first touch insulating layer 183. The touch black matrix TBM can include materials capable of absorbing light. The touch black matrix TBM can include a black pigment or dye, but is not limited thereto. The touch black matrix TBM can prevent a defect, such as light leakage that can occur between the pixels PX, etc.

The second touch insulating layer 184 can be disposed on the touch black matrix TBM. The second touch electrode 185 can be disposed on the second touch insulation layer 184. The third touch insulating layer 186 can be disposed on the second touch electrode 185. The third touch insulating layer 186 can be formed of the same material as the first touch insulating layer 183, but is not limited thereto.

A microlens ML (ML1 and ML2) can be disposed on the third touch insulating layer 186.

A first microlens ML1 can correspond to the first sub-pixel PX1, and a second microlens ML2 can correspond to the second sub-pixel PX2.

The microlens ML can include a hemispherical or semi-cylindrical shape, but is not limited thereto. The shape of the microlens ML can vary according to the size, shape, etc. of the light-emitting area EA.

The microlenses ML1 and ML2 can control paths of light emitted from the pixels PX1 and PX2, respectively. The microlenses ML1 and ML2 can control the paths of the light emitted from the pixels PX1 and PX2 in different directions.

For example, the first microlens ML1 can control light emitted from the first sub-pixel PX1 to travel toward one side in the first direction DR1 in a plan view, and the second microlens ML2 can control light emitted from the second sub-pixel PX2 to travel toward the other side in the first direction DR1 in a plan view.

Accordingly, the pixels PX1 and PX2 can display different images and videos, and the display apparatus 1 (see FIG. 1) can display two different images and videos according to a viewing angle.

When the display apparatus 1 (see FIG. 1) is used for a vehicle, a screen displayed to the driver DRIVER sitting on the driver's seat and a screen displayed to the passenger CO-DRIVER sitting on the passenger's seat can be controlled separately, and different screens can be displayed to the driver DRIVER and the passenger CO-DRIVER.

However, the embodiments of the present disclosure are not limited thereto, and one of the pixels PX1 and PX2 can provide a screen displayed to both the driver DRIVER and the passenger CO-DRIVER.

In addition, by arranging the microlens ML (ML1 and ML2), it is possible to secure a wide viewing angle characteristic, increase luminance, and block leaked light, reflected light, etc., thereby preventing light leakage.

The microlens ML can include a division line DV (DV1 and DV2). The division line DV can include a first division line DV1 and a second division line DV2.

The division line DV can refer to a virtual line that divides the microlens ML into two parts. The microlens ML can be divided into two substantially equal parts through the division line DV, but is not limited thereto. The two parts of the microlens ML divided by the division line DV can include a symmetrical shape, but is not limited thereto, and the two parts of the microlens ML divided by the division line DV can have different shapes and sizes.

The division line DV (DV1 and DV2) can be misaligned with a center EC (EC1 and EC2) of the light-emitting area EA, but is not limited thereto.

A first center EC1 can refer to the center of the first light-emitting area EA1 of the first sub-pixel PX1, and a second center EC2 can refer to the center of the second light-emitting area EA2 of the second sub-pixel PX2.

The first microlens ML1 can include the first division line DV1, and the second microlens ML2 can include the second division line DV2.

In addition, at least a part of the light-emitting part 150 can be disposed to be inclined in the thickness direction (the third direction DR3).

Specifically, in the area in which the light-emitting part 150 is disposed, a part of an upper surface of the second protective layer 112 can be formed to be inclined. The light-emitting part 150 can be disposed on the second protective layer 112 of which at least a part is inclined. Accordingly, at least a part of each of the anode electrode 151 and the organic layer 152 can be tilted. The at least a part of each of the anode electrode 151 and the organic layer 152 can be tilted (inclined) toward the microlens ML.

Each of the anode electrode 151 and the organic layer 152 can be disposed on the second protective layer 112 of which at least a part is inclined. The organic layer 152 can be disposed on the second protective layer 112 of which the entire area is inclined, but is not limited thereto.

The anode electrode 151 and the organic layer 152 that are disposed on the inclined second protective layer 112 can be disposed to be inclined (tilted) corresponding to the inclined second protective layer 112. Accordingly, a part of the cathode electrode 153 disposed on the organic layer 152 can be disposed to be inclined.

The anode electrode 151 and the organic layer 152 can be disposed to be inclined in the thickness direction (the third direction DR3) of the display panel 100 in the first light-emitting area EA1, the second light-emitting area EA2, and surrounding areas thereof. An upper surface of the anode electrode 151 and an upper surface of the organic layer 152 can be tilted in the thickness direction (the third direction DR3) of the display panel 100. A direction in which the upper surface of the anode electrode 151 and the upper surface of the organic layer 152 face can be tilted in the thickness direction (the third direction DR3) of the display panel 100.

The upper surface of the anode electrode 151 and the upper surface of the organic layer 152 can be tilted with respect to an upper surface of the first protective layer 111.

The anode electrode 151 and the organic layer 152 of the first sub-pixel PX1 can be inclined in a different direction from the anode electrode 151 and the organic layer 152 of the second sub-pixel PX2. For example, in the first light-emitting area EA1, the second light-emitting area EA2, and peripheries thereof, the directions in which the anode electrode 151 and the organic layer 152 are tilted can be opposite.

The upper surface of the anode electrode 151 and the upper surface of the organic layer 152 of the first sub-pixel PX1 can be tilted toward the first microlens ML1, and the upper surface of the anode electrode 151 and the upper surface of the organic layer 152 of the second sub-pixel PX2 can be tilted toward the second microlens ML2.

Accordingly, light emitted from each pixel PX can be tilted with respect to the thickness direction (the third direction DR3) of the display panel 100.

The first center EC1 of the first light-emitting area EA1 of the first pixel PX1 and the first division line DV1 of the first microlens ML1 disposed on the first sub-pixel PX1 can be misaligned. The second center EC2 of the second light-emitting area EA2 of the second sub-pixel PX2 and the second division line DV2 of the second microlens ML2 disposed on the second sub-pixel PX2 can be misaligned.

A direction in which the first center EC1 and the first division line DV1 are misaligned can differ from a direction in which the second center EC2 and the second division line DV2 are misaligned. For example, the direction in which the first center EC1 and the first division line DV1 are misaligned and the direction in which the second center EC2 and the second division line DV2 are misaligned can be opposite, but are not limited thereto.

The opening (or the light-emitting area EA) of the pixel PX and the light-emitting part 150 disposed around the opening can be disposed to be inclined in the thickness direction (the third direction DR3), and light L1 and L2 emitted from the light-emitting part 150 can travel in a direction inclined with respect to the thickness direction (the third direction DR3).

As the microlens ML and the light-emitting area EA are misaligned, even when the light L1 and L2 emitted from the light-emitting part 150 travels while being tilted with respect to the thickness direction (the third direction DR3), each light L1 or L2 can travel toward the microlens ML of each pixel PX.

The first sub-pixel PX1 can emit the light L1 tilted to the left in a cross-sectional view. The second sub-pixel PX2 can emit the light L2 to be tilted to the right in a cross-sectional view.

The direction and degree of the misalignment between the microlens ML and the light-emitting area EA can vary according to the traveling direction of the light emitted from each pixel PX1 or PX2.

As the light-emitting part 150 of each pixel PX (PX1 or PX2) is tilted, the path of the light emitted from each pixel PX1 or PX2 can be more easily controlled, and different images and videos can be displayed more clearly according to a viewing angle.

A lens protective layer 190 can be disposed on the microlens ML (ML1 and ML2). The lens protective layer 190 can include an organic insulation material, but is not limited thereto. The lens protective layer 190 can protect the microlens ML by covering the microlens ML.

A refractive index of the lens protective layer 190 can be smaller than a refractive index of the microlens ML. Accordingly, due to a difference in refractive index between the microlens ML and the lens protective layer 190, light that has passed through the microlens ML can be prevented from being reflected toward the substrate 101.

The deco layer DCL can be disposed on the lens protective layer 190.

Hereinafter, the deco layer DCL will be described in detail.

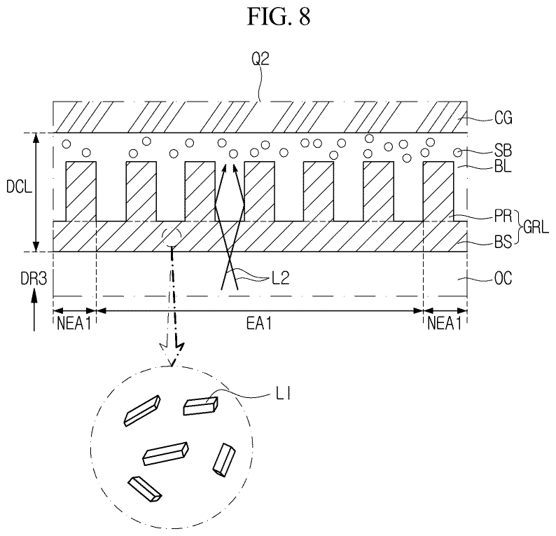

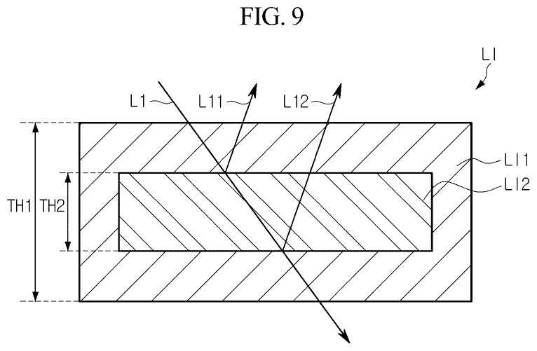

FIG. 8 is an enlarged view of area Q2 in FIG. 3. FIG. 9 is a cross-sectional view of optical interference particles according to one embodiment of the present disclosure.

Referring further to FIGS. 3, 8 and 9, the deco layer DCL can be disposed on the display panel 100. The deco layer DCL can be bonded to the display panel 100 by an OTA or a PSA.

The deco layer DCL can include a grid layer GRL including a base portion BS and a protrusion portion PR protruding from the base portion BS toward the cover layer CG, a base layer BL covering the protrusion portion PR, and scatterers SB disposed in a dispersed manner within the base layer BL. The protrusion portion PR can be provided as a plurality of protrusions. The base portion BS and the protrusion portion PR can be formed integrally, but are not limited thereto.

The base portion BS and the protrusion portion PR can be manufactured by micro-molding a deco coating layer coated on the planarization layer OC, but the manufacturing method is not limited thereto.

The grid layer GRL can provide the visual sense, colors, etc. when the display apparatus 1 is turned off. The grid layer GRL can include a plurality of optical interference particles LI. The plurality of optical interference particles LI can be disposed in a dispersed manner within the grid layer GRL. The optical interference particles LI can be formed in a hexahedral shape, but is not limited thereto.

The optical interference particles LI can have a core-shell structure having two layers that have different refractive indexes. The optical interference particles LI can include a first light reflective layer LI1 and a second light reflective layer LI2 that have different refractive indexes. The first light reflective layer LI1 can be disposed to surround the second light reflective layer LI2. The optical interference particles LI can have a first thickness TH1.

In addition, in the present embodiment, only one type of optical interference particles LI is described, but the embodiments of the present disclosure are not limited thereto. The optical interference particles LI can include two or more different types. Accordingly, the grid layer GRL can implement various colors and patterns according to a design.

A refractive index of the first light reflective layer LI1 can be greater than a refractive index of the second light reflective layer LI2. The embodiments of the present disclosure are not limited thereto, but the refractive index of the first light reflective layer LI1 can be 1.6 or more, and the refractive index of the second light reflective layer LI2 can be 1.5 or less.

The first light reflective layer LI1 can include at least one metal oxide material among TiO₂, CeO₂, and Ta₂O₅. The second light reflective layer LI2 can include at least one oxide material among SiO₂ and Al₂O₃.

Since the grid layer GRL includes optical interference particles LI, light of a specific color can be reflected according to the first thickness TH1 of the optical interference particles LI so that the display apparatus 1 can display a specific reflected color even while being turned off. In addition, since the optical interference particles LI only reflect or transmit light without absorbing light, a transmittance of the grid layer GRL can be high. Accordingly, it is possible to suppress or prevent a reduction in luminous efficiency of the display apparatus 1. In addition, it is possible to improve the aesthetics of the display apparatus 1, and since integration with surroundings is possible, it is possible to improve the overall interior aesthetics.

Since the optical interference particles LI include the first light reflective layer LI1 and the second light reflective layer LI2 that have different refractive indexes, the optical interference particles LI can be reflected at a boundary between the first light reflective layer LI1 and the second light reflective layer LI2 according to the path of the light L1. The reflected light L11 and L12 reflected between the first light reflective layer LI1 and the second light reflective layer LI2 can be subjected to constructive interference.

The second light reflective layer LI2 can have a second thickness TH2, and the second thickness TH2 can be adjusted so that constructive interference of a desired color can be achieved. Accordingly, the visual sense, colors, etc. provided by the grid layer GRL can be supplemented, thereby providing clearer visual sense, colors, etc. in the OFF state.

The base portion BS can be disposed on the planarization layer OC and disposed across the entire area of the planarization layer OC, but is not limited thereto. The base portion BS can provide a space in which the protrusion portion PR can be disposed.

The protrusion portion PR can protrude from the base portion BS toward the cover layer CG in the third direction DR3. The protrusion portion PR can be disposed across the entire area of the base portion BS. The protrusion portion PR can be provided as a plurality of protrusions (also referred to as protrusion portions), and adjacent protrusion portions PR can be disposed to be spaced apart by a predetermined distance from each other.

The protrusion portion PR can be formed in a rectangular pillar shape with a predetermined width in a cross-sectional view, but is not limited thereto.

In at least one of the light-emitting area EA1, EA2, or EA3, the plurality of protrusion portions PR can be disposed, but the embodiments of the present disclosure are not limited thereto.

By arranging the protrusion portions PR, the light emitted from the light-emitting areas EA1, EA2, and EA3 can be condensed, thereby increasing the luminance of the display apparatus 1. For example, the light L2 emitted from the light-emitting areas EA1, EA2, and EA3 can be condensed while being reflected between the protrusion portions PR and the base layer BL and can travel toward the cover layer CG. Accordingly, even when the grid layer GRL is disposed for the OFF visual sense and color of the display apparatus 1, it is possible to minimize a reduction in luminance of the display apparatus 1.

By arranging the grid layer GRL, it is possible to improve the OFF visual sense and color of the display apparatus 1, and even when the grid layer GRL is disposed to implement the visual sense and texture, it is possible to minimize a reduction in luminance. Furthermore, it is possible to implement a low power display apparatus, thereby reducing power consumption of the display apparatus.

The base layer BL can be disposed on the grid layer GRL. The base layer BL can cover a step caused by the protrusion portion PR and planarize a surface formed by the protrusion portion PR. The base layer BL can include one or more selected from an acryl-based resin, an epoxy-based resin, a siloxane-based resin, a urethane-based resin, etc., but is not limited thereto.

A plurality of scatterers SB can be disposed in a dispersed manner within the base layer BL. The plurality of scatterers SB can include a transparent oxide. For example, the scatterers SB can include at least one selected from the silicon oxide (SiOₓ) or polycycloolefin (PCO)-based materials.

As the scatterers SB are disposed, the light emitted from the pixel PX can be scattered, and a reflection visual sense deviation according to a viewing angle can be reduced.

Hereinafter, other embodiments of the present disclosure will be described. For contents that are substantially the same as those described with reference to FIGS. 1 to 9 among components included in other embodiments, the same reference numerals are given, and the overlapping contents can be omitted or briefly described.

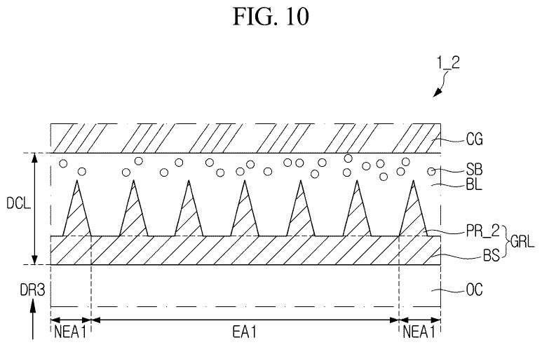

FIG. 10 is a cross-sectional view of a display apparatus according to another embodiment of the present disclosure. Particularly, FIG. 10 illustrates a cross section of the first sub-pixel PX1 around the deco layer DCL.

Referring to FIG. 10, a display apparatus 1_2 according to the present embodiment can include the grid layer GRL, the grid layer GRL can include the base portion BS and a protrusion portion PR_2, and the protrusion portion PR_2 can be formed in a triangular pyramid shape in a cross section. The protrusion portion PR_2 can be formed in a triangular pyramid shape of which width decreases from the base portion BS toward the cover layer CG.

In this case, the light emitted from the first light-emitting area EA1 can be condensed by the protrusion portion PR_2. In addition, since the protrusion portion PR_2 is formed in a triangular pyramidal shape in a cross section, an area in which the protrusion portion PR_2 covers the light emitted from the first light-emitting area EA1 can be reduced, thereby more smoothly suppress or prevent a reduction in luminance of the display apparatus 1_2.

Even in this case, by arranging the grid layer GRL, it is possible to improve the OFF visual sense and color of the display apparatus 1_2, and even when the grid layer GRL is disposed to implement the visual sense and texture, it is possible to minimize a reduction in luminance. Furthermore, it is possible to implement a low power display apparatus, thereby reducing power consumption of the display apparatus.

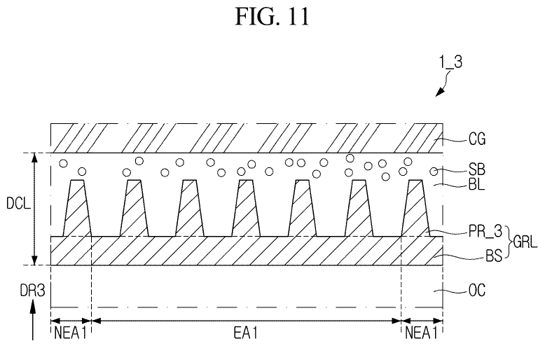

FIG. 11 is a cross-sectional view of a display apparatus according to still another embodiment of the present disclosure. Particularly, FIG. 11 illustrates a cross section of the first sub-pixel PX1 around the deco layer DCL.

Referring to FIG. 11, a display apparatus 1_3 according to the present embodiment can include the grid layer GRL, the grid layer GRL can include the base portion BS and a protrusion portion PR_3, and the protrusion portion PR_3 can be formed in a triangular pyramid shape in a cross section. The protrusion portion PR_3 can be formed in a triangular pyramid shape of which width decreases from the base portion BS toward the cover layer CG.

In this case, the light emitted from the first light-emitting area EA1 can be condensed by the protrusion portion PR_3. In addition, since the protrusion portion PR_3 is formed in a triangular pyramidal shape in a cross section, an area in which the protrusion portion PR_3 covers the light emitted from the first light-emitting area EA1 can be reduced, thereby more smoothly suppress or prevent a reduction in luminance of the display apparatus 1_3.

Even in this case, by arranging the grid layer GRL, it is possible to improve the OFF visual sense and color of the display apparatus 1_3, and even when the grid layer GRL is disposed to implement the visual sense and texture, it is possible to minimize a reduction in luminance. Furthermore, it is possible to implement a low power display apparatus, thereby reducing power consumption of the display apparatus.

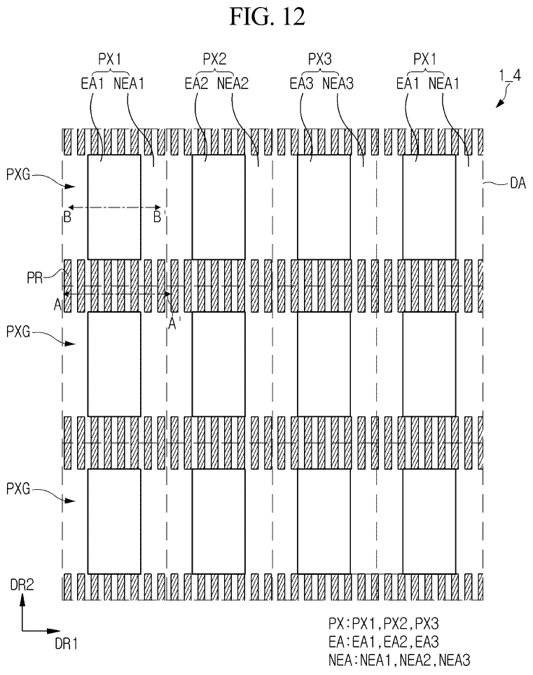

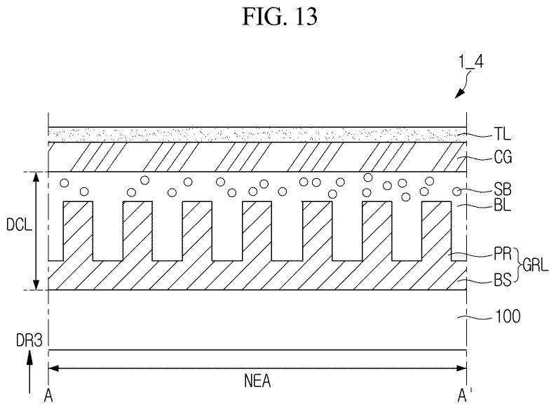

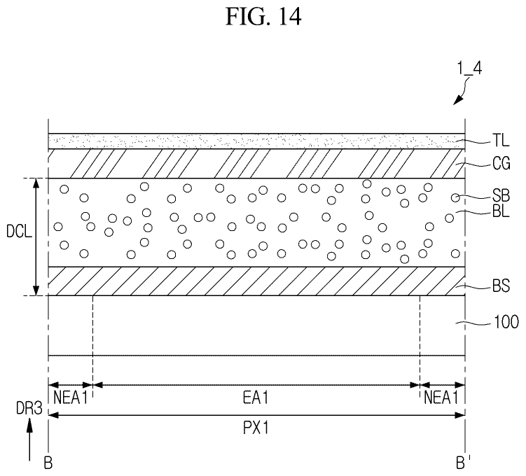

FIG. 12 is a plan view of a display apparatus according to yet another embodiment of the present disclosure. FIG. 13 is a cross-sectional view along line A-A′ in FIG. 12. FIG. 14 is a cross-sectional view along line B-B′ in FIG. 12.

Referring to FIGS. 12 to 14, the protrusion portion PR of the display apparatus 1_4 according to the present embodiment can be disposed in the non-light-emitting area NEA and may not be disposed in the light-emitting area EA. The protrusion portion PR can be disposed only in a part of the non-light-emitting area NEA, but is not limited thereto, and can be disposed across the entire area of the non-light-emitting area NEA.

The first sub-pixel PX1, the second sub-pixel PX2, and the third sub-pixel PX3 can be alternately disposed repeatedly in the first direction DR1. Each of the first sub-pixel PX1, the second sub-pixel PX2, and the third sub-pixel PX3 can be disposed repeatedly in the second direction DR2.

The display apparatus 1_4 can further include a pixel group PXG. The pixel group PXG can include a plurality of first sub-pixels PX1, a plurality of second sub-pixels PX2, and a plurality of third sub-pixels PX3 that are alternately disposed repeatedly in the first direction DR1. The pixel group PXG can be disposed repeatedly in the second direction DR2.

The base portion BS can be disposed across the light-emitting area EA and the non-light-emitting area NEA. The protrusion portion PR can be disposed in the non-light-emitting area NEA and may not be disposed in the light-emitting area EA.

The protrusion portion PR can extend in the second direction DR2 and can be disposed repeatedly in the first direction DR1. In this case, the protrusion portion PR can be disposed between the light-emitting area EA (EA1, EA2, and EA3) of each pixel group PXG. The protrusion portion PR can be disposed in the non-light-emitting area NEA (NEA1, NEA2, and NEA3) disposed between the light-emitting areas EA (EA1, EA2, and EA3) of the sub-pixels PX1, PX2, and PX3 disposed in the pixel groups PXG adjacent to each other in the second direction DR2.

The protrusion portion PR can be disposed in the first non-light-emitting area NEA1 between the first light-emitting areas EA1 of the first sub-pixels PX1 adjacent to each other in the second direction DR2, the second non-light-emitting area NEA2 between the second light-emitting areas EA2 of the second sub-pixels PX2 adjacent to each other in the second direction DR2, and the third non-light-emitting area NEA3 between the third light-emitting areas EA3 of the third sub-pixels PX3 adjacent to each other in the second direction DR2.

In this case, since the protrusion portion PR is not disposed in the light-emitting area EA, it is possible to suppress or prevent a reduction in luminance in the light-emitting area EA.

Even in this case, by arranging the grid layer GRL, it is possible to improve the OFF visual sense and color of the display apparatus 1_4, and even when the grid layer GRL is disposed to implement the visual sense and texture, it is possible to minimize a reduction in luminance. Furthermore, it is possible to implement a low power display apparatus, thereby reducing power consumption of the display apparatus.

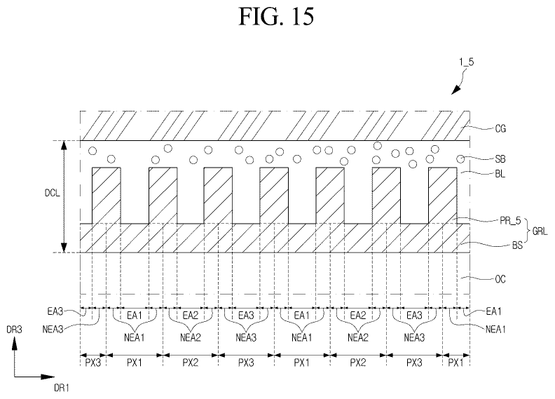

FIG. 15 is a cross-sectional view of a display apparatus according to yet another embodiment of the present disclosure. Particularly, FIG. 15 illustrates a cross section around the deco layer DCL.

Referring to FIG. 15, in a display apparatus 1_5 according to the present embodiment, a protrusion portion PR_5 is not disposed in the light-emitting areas EA1, EA2, and EA3, and the protrusion portion can be disposed in the non-light-emitting areas NEA1, NEA2, and NEA3.

The protrusion portion PR_5 can be disposed repeatedly in the first direction DR1, and the light-emitting areas EA1, EA2, and EA3 can be disposed between adjacent protrusion portions PR_5. Each of the light-emitting areas EA1, EA2, and EA3 can be disposed between adjacent protrusion portions PR_5.

FIG. 15 illustrates the protrusion portion PR_5 disposed across all areas of the non-light-emitting areas NEA1, NEA2, and NEA3, but the embodiments of the present disclosure are not limited thereto. For example, a width of each of the non-light-emitting areas NEA1, NEA2, and NEA3 in the first direction DR1 can be greater than a width of each of the protrusion portions PR_5 in the first direction DR1.

In this case, since the protrusion portion PR_5 is not disposed in the light-emitting area EA, it is possible to suppress or prevent a reduction in luminance in the light-emitting area EA.

Even in this case, by arranging the grid layer GRL, it is possible to improve the OFF visual sense and color of the display apparatus 1_5, and even when the grid layer GRL is disposed to implement the visual sense and texture, it is possible to minimize a reduction in luminance. Furthermore, it is possible to implement a low power display apparatus, thereby reducing power consumption of the display apparatus.

A display apparatus according to various embodiments of the present disclosure can be described as follows.

According to embodiments of the present disclosure, there is provided a display apparatus including a display panel, a grid layer disposed on the display panel and including a base portion and a protrusion portion protruding from the base portion, and a cover layer disposed on the grid layer, in which the grid layer includes a plurality of optical interference particles.

According to various embodiments of the present disclosure, the optical interference particle can include a core-shell structure having different refractive indexes.

According to various embodiments of the present disclosure, the optical interference particle can include a first light reflective layer and a second light reflective layer surrounded by the first light reflective layer, and a refractive index of the first light reflective layer can be greater than a refractive index of the second light reflective layer.

According to various embodiments of the present disclosure, the first light reflective layer can include at least one metal oxide material among TiO₂, CeO₂, and Ta₂O₅, and the second light reflective layer can include at least one oxide material among SiO₂ and Al₂O₃.

According to various embodiments of the present disclosure, the display apparatus can further include a sub-pixel including a light-emitting area and a non-light-emitting area disposed around the light-emitting area, in which a plurality of the protrusion portions can be disposed in the light-emitting area.

According to various embodiments of the present disclosure, the protrusion portions can protrude from the base portion toward the cover layer.

According to various embodiments of the present disclosure, the display apparatus can further include a plurality of sub-pixels including a light-emitting area and a non-light-emitting area disposed around the light-emitting area, in which the protrusion portion can be repeatedly disposed in a first direction and disposed between the light-emitting areas of adjacent sub-pixels in a second direction intersecting the first direction.

According to various embodiments of the present disclosure, the protrusion portion can extend in the second direction.

According to various embodiments of the present disclosure, the display apparatus can further include a base layer disposed between the grid layer and the cover layer, and a plurality of scatterers disposed in a dispersed manner within the base layer.

According to various embodiments of the present disclosure, the display panel can include a first sub-pixel, a second sub-pixel, a third sub-pixel that emit light of different colors, and a color filter disposed in each sub-pixel, and the grid layer can be disposed between the color filter and the cover layer.

According to various embodiments of the present disclosure, the display panel can further include a substrate, a thin film transistor disposed on the substrate, a light-emitting part connected to the thin film transistor, an encapsulation part disposed on the light-emitting part, and a touch layer disposed on the encapsulation part, and the color filter can be disposed between the touch layer and the grid layer.

According to various embodiments of the present disclosure, the display apparatus can further include a black matrix disposed between the color filters disposed in each sub-pixel, in which the color filter can be disposed on the black matrix.

According to various embodiments of the present disclosure, the display apparatus can further include a display area that displays a screen and a non-display area disposed around the display area, in which the grid layer can be disposed in the display area.

According to various embodiments of the present disclosure, the display apparatus can further include a texture layer disposed on the cover layer.

According to embodiments of the present disclosure, there is provided a display apparatus including a substrate, a thin film transistor disposed on the substrate, a light-emitting part disposed on the thin film transistor and connected to the thin film transistor, an encapsulation part disposed on the light-emitting part, a touch layer disposed on the encapsulation part, a color filter disposed on the touch layer, a deco layer disposed on the color filter, and a cover layer disposed on the deco layer, in which the deco layer is disposed between the color filter and the cover layer and includes a plurality of optical interference particles.

According to various embodiments of the present disclosure, the deco layer can include a base portion and a protrusion portion protruding from the base portion, and the plurality of optical interference particles can be disposed in the base portion and the protrusion portion.

According to various embodiments of the present disclosure, the optical interference particle can include a core-shell structure having different refractive indexes.

According to various embodiments of the present disclosure, the optical interference particle can include a first light reflective layer and a second light reflective layer surrounded by the first light reflective layer, and a refractive index of the first light reflective layer can be greater than a refractive index of the second light reflective layer.

According to various embodiments of the present disclosure, the display apparatus can further include a sub-pixel disposed on the substrate and including a light-emitting area and a non-light-emitting area disposed around the light-emitting area, and a plurality of protrusion portions can be disposed in the light-emitting area.

According to various embodiments of the present disclosure, the color filter can be disposed between the touch layer and the deco layer.

Although the embodiments have been described above with reference to the accompanying drawings, those skilled in the art to which the present disclosure pertains will be able to understand that the above-described technical configuration can be carried out in other specific forms without changing the technical spirit or essential features thereof. Accordingly, it should be understood that the above-described embodiments are illustrative and not restrictive in all respects. In addition, the scope of the embodiments is determined by the appended claims rather than detailed description. In addition, the meaning and scope of the claims and all changed or modified forms derived from the equivalent concept thereof should be construed as being included in the scope of the embodiments of the present disclosure.

### DESCRIPTION OF REFERENCE NUMERALS

1: display apparatus
100: display panel
DA: display area
NDA: non-display area
PX: pixel
PXG: pixel group
EA: light-emitting area
NEA: non-light-emitting area
DCL: deco layer
GRL: grid layer
BS: base portion
PR: protrusion portion
LI: optical interference particles
BL: base layer
SB: scatterer
CG: cover layer
TL: texture layer

What is claimed is:

1. A display apparatus comprising:
a display panel;
a grid layer disposed on the display panel and including a base portion and a protrusion portion protruding from the base portion; and
a cover layer disposed on the grid layer,
wherein the grid layer includes a plurality of optical interference particles.

2. The display apparatus of claim 1, wherein each of the plurality of optical interference particles includes a core-shell structure having different refractive indexes.

3. The display apparatus of claim 2, wherein each of the plurality of optical interference particles includes a first light reflective layer and a second light reflective layer surrounded by the first light reflective layer, and
a refractive index of the first light reflective layer is greater than a refractive index of the second light reflective layer.

4. The display apparatus of claim 3, wherein the first light reflective layer includes at least one metal oxide material among TiO₂, CeO₂, and Ta₂O₅, and
the second light reflective layer includes at least one oxide material among SiO₂ and Al₂O₃.

5. The display apparatus of claim 1, wherein the display panel includes a sub-pixel having a light-emitting area and a non-light-emitting area disposed around the light-emitting area,
the protrusion portion of the grid layer includes a plurality of protrusions, and
the plurality of protrusions are disposed in the light-emitting area.

6. The display apparatus of claim 5, wherein the plurality of protrusions of the grid layer protrude from the base portion of the grid layer toward the cover layer.

7. The display apparatus of claim 1, wherein the display panel includes a sub-pixel having a light-emitting area and a non-light-emitting area disposed around the light-emitting area,
the protrusion portion of the grid layer is repeatedly disposed in a first direction and disposed between light-emitting areas of adjacent sub-pixels in a second direction intersecting the first direction.

8. The display apparatus of claim 7, wherein the protrusion portion of the grid layer extends in the second direction.

9. The display apparatus of claim 1, further comprising:
a base layer disposed between the grid layer and the cover layer; and
a plurality of scatterers disposed in a dispersed manner within the base layer.

10. The display apparatus of claim 1, wherein the display panel includes a first sub-pixel, a second sub-pixel, a third sub-pixel that are configured to emit light of different colors, and a color filter disposed in each of the first to third sub-pixels, and
the grid layer is disposed between the color filter and the cover layer.

11. The display apparatus of claim 10, wherein the display panel further includes a substrate, a thin film transistor disposed on the substrate, a light-emitting part connected to the thin film transistor, an encapsulation part disposed on the light-emitting part, and a touch layer disposed on the encapsulation part, and
the color filter is disposed between the touch layer and the grid layer.

12. The display apparatus of claim 10, further comprising a black matrix disposed between the color filters disposed in the first to third sub-pixels,
wherein the color filter is disposed on the black matrix.

13. The display apparatus of claim 1, further comprising a display area configured to display a screen and a non-display area disposed around the display area,
wherein the grid layer is disposed in the display area.

14. The display apparatus of claim 1, further comprising a texture layer disposed on the cover layer.

15. A display apparatus comprising:
a thin film transistor disposed on a substrate;
a light-emitting part disposed on the thin film transistor and connected to the thin film transistor;
an encapsulation part disposed on the light-emitting part;
a touch layer disposed on the encapsulation part;
a color filter disposed on the touch layer;
a deco layer disposed on the color filter; and
a cover layer disposed on the deco layer,
wherein the deco layer is disposed between the color filter and the cover layer, and includes a plurality of optical interference particles.

16. The display apparatus of claim 15, wherein the deco layer includes a base portion and a protrusion portion protruding from the base portion, and
the plurality of optical interference particles are disposed in the base portion and the protrusion portion.

17. The display apparatus of claim 16, wherein each of the plurality of optical interference particles includes a core-shell structure having different refractive indexes.

18. The display apparatus of claim 17, wherein each of the plurality of optical interference particles includes a first light reflective layer and a second light reflective layer surrounded by the first light reflective layer, and
a refractive index of the first light reflective layer is greater than a refractive index of the second light reflective layer.

19. The display apparatus of claim 15, wherein the display panel includes a sub-pixel disposed on the substrate and having a light-emitting area and a non-light-emitting area disposed around the light-emitting area, and
a plurality of protrusion portions of the deco layer are disposed in the light-emitting area.

20. The display apparatus of claim 15, wherein the color filter is disposed between the touch layer and the deco layer.
